(19) United States
(12) Patent Application Publication
(10) Pub. No.: US 2026/0246603 A1
(43) Pub. Date: Aug. 20, 2026

(54) COMMUNICATION SYSTEMS AND METHODS FOR ENERGY EFFICIENT CLOCKLESS WAKE-UP RECEIVER BODY AREA NETWORKS

(71) Applicant: Quasistatics Inc., West Lafayette, IN (US)

(72) Inventors: Lingke Ding, Lafayette, IN (US); Shreyas Sen, West Lafayette, IN (US)

(21) Appl. No.: 19/053,727

(22) Filed: Feb. 14, 2025

(51) Int. Cl. H04L 7/033; H03L 7/08; H04B 13/00; H04W 52/02

(52) U.S. Cl. CPC H04L 7/033; H03L 7/0807

(57) ABSTRACT

The present invention relates to communication system for energy efficient clockless wake-up receiver with dynamic clock generation in Body Area Networks (BAN) using a Human Body Communication (HBC) network. The communication system comprises a wake-up receiver unit configured to operate in a constant active low-power mode for constantly listening to one or more input signals received from a transmitter, in which the wake-up receiver unit may operate in constant low-power activated mode using leakage power. Further, the communication system comprises an intermittently operation unit connected to the wake-up receiver unit, in which the intermittently operation unit further comprises a clock generation unit configured to switch to a clock recovery mode for extracting a clock from the one or more modulated data streams, in which the clock generation unit may switch to a clock maintained mode, for maintaining clock frequency during absence of the one or more modulated data streams.

### TECHNICAL FIELD

Embodiments of the present disclosure generally relate to Human Body Communication (HBC) technologies, and more particularly relates to a communication system and method for energy efficient clockless wake-up receiver with dynamic clock generation in Body Area Networks (BAN) using a Human Body Communication (HBC) network.

### BACKGROUND

The requirements of low-power, wireless communication around the body as an alternative to traditional wireless communication such as Wireless Fidelity (Wi-Fi), and Bluetooth, have led to the invention of the Human Body Communication (HBC) network exploiting the conductive property of the human body. The application of the HBC is found in wearable devices such as smartwatches for receiving physiological information from different sensor nodes around the body.

Energy-efficient communication systems are essential for Ultra-Low-Power (ULP) applications, particularly in wearable devices and Internet of Things (IoT). However, these existing systems face challenges in balancing power consumption, responsiveness, and efficiency. Traditional systems rely on always-running clocks, which increases idle power consumption and add size and cost due to the need for external crystal oscillators. Recent advances in ULP technology address some issues but still rely upon external references or compromise latency and energy efficiency.

Energy constraint wearables tend to operate in a duty-cycled manner in which the majority of their time is spent in an idle state to conserve energy. To further reduce idle state energy, a wake up receiver is typically used such that the majority of the device could be shut off while still maintaining responsiveness. An always-running clock increases this idle state power consumption.

More specifically, energy-efficient communication systems have become critical for Ultra-Low-Power (ULP) applications, particularly in wearable devices and the Internet of Things (IoT). These systems often face challenges in maintaining low power consumption without compromising responsiveness and operational efficiency. Energy-constrained wireless transceivers with wake-up receivers (WuRX) traditionally rely on an always-running clocks for sampling incoming data and performing digital correlation. This approach necessitates local oscillator calibration through a reference source, such as a crystal oscillator, which increases power consumption during idle periods and adds significant size and cost to the system. However, eliminating the always-running clock reduces system power consumption to leakage levels during idle states, but requires innovative methodologies to implement wake-up functionality while ensuring low latency. Additionally, the absence of an external clock reference demands advanced techniques for clock synchronization.

For example, as shown in (a) of FIG. 1, a traditional First-in, First-out (FIFO)-based Wake-up Receiver (WuRX) 100 rely on a clock signal (CLK) to propagate data (Data In) between memory blocks, such as delayed flip-flops (DFFs) 101a-n. In the traditional First-in, First-out (FIFO)-based Wake-up Receiver (WuRX) 100, the data (Data In) moves through the DFF chain at each rising or falling edge of the clock (CLK), and a clocked comparator 103 (also referred as a comparator 103) checks the data bits (S1, S2, S3, S4, S5) against a predefined code pattern, as shown in (b) of FIG. 1. A wake-up signal is generated only when the data bits (S1, S2, S3, S4, S5) matches the predefined code pattern. For example, as shown in (b) of FIG. 1, the specific code pattern includes 11101. When the data bits (S1, S2, S3, S4, S5) match the code pattern 11101, the comparator 103 generates the wake up signal such that the traditional First-in, First-out (FIFO)-based Wake-up Receiver (WuRX) 100 may activate one or more components.

Recent technological developments in the solid-state community aimed at ULP wearables have achieved substantial energy efficiency and low latency. However, the existing solutions still face limitations, such as reliance on always-running clocks or ULP clock generation units requiring external references, highlighting the need for novel ULP and low-latency solutions. One of the existing system demonstrates a ULP WuRX with a power consumption of 17 nW, but produces a high latency of 2 ms, which is a major drawback due to the ULP clocks operating at 4 kHz. Similarly, another existing system presents a ULP WuRX with 200 μs latency, but incurs a high power consumption of 220 μW, limiting utility of the existing system for battery-less nodes. Further, one of the existing system showcases a battery-less wearable node with a peak power consumption of only 13.96 μW, yet the existing system relies on an external crystal oscillator for clocking, undermining energy efficiency benefits. Yet, another existing system proposes ULP crystal-less designs, which depend on external reference voltages for calibration or forwarded clock signals through power or amplitude shift keying (ASK), reducing versatility of the existing system across diverse use cases.

Therefore, a need exists for a novel solution that overcomes the limitations of above-mentioned problems. Thus, there is a need in the art to provide a communication system and method for energy efficient clockless wake-up receiver with dynamic clock generation in Body Area Networks (BAN) using a Human Body Communication (HBC) network, to address the aforementioned deficiencies in the art.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

An aspect of the present disclosure provides a communication system for energy efficient clockless wake-up receiver with dynamic clock generation in Body Area Networks (BAN) using a Human Body Communication (HBC) network. The communication system comprises a wake-up receiver unit configured to operate in a constant active low-power mode for constantly listening to one or more input signals received from a transmitter, in which the wake-up receiver unit may operate in the constant low-power activated mode using leakage power. Further, the communication system comprises an intermittently operation unit connected to the wake-up receiver unit, in which the intermittently operation unit further comprises a clock generation unit configured to switch to a clock recovery mode for extracting a clock from the one or more modulated data streams. In an embodiment, the clock generation unit may switch to a clock maintained mode, for maintaining a clock frequency during absence of the one or more modulated data streams, in which in the clock recovery mode, the clock generation unit may be configured to extract and recover a desired carrier clock frequency from the one or more modulated data streams. Further, in an embodiment, in the clock maintained mode, the clock generation unit may be configured to preserve a recovered clock frequency to provide a stable reference for system blocks in the absence of the one or more modulated data streams.

Another aspect of the present disclosure includes a communication method for energy efficient clockless wake-up receiver with dynamic clock generation in Body Area Networks (BAN) using a Human Body Communication (HBC) network. The communication method includes operating, by a wake-up receiver unit, in a constant active low-power mode for constantly listening to one or more input signals received from a transmitter, in which the wake-up receiver unit may operate in the constant low-power activated mode using leakage power. Further, the communication method includes switching, by a clock generation unit, to a clock recovery mode for extracting a clock from the one or more modulated data streams. In an embodiment, the clock generation unit may switch to a clock maintained mode, for maintaining a clock frequency during absence of the one or more modulated data streams, in which in the clock recovery mode, the clock generation unit may be configured to extract and recover a desired carrier clock frequency from the one or more modulated data streams. Further, in an embodiment, in the clock maintained mode, the clock generation unit may be configured to preserve a recovered clock frequency to provide a stable reference for system blocks in the absence of the one or more modulated data streams.

To further clarify the advantages and features of the present disclosure, a more particular description of the disclosure will follow by reference to specific embodiments thereof, which are illustrated in the appended figures. It is to be appreciated that these figures depict typical embodiments of the disclosure and are therefore not to be considered limiting in scope. The disclosure will be described and explained with additional specificity and detail with the appended figures.

### BRIEF DESCRIPTION OF ACCOMPANYING DRAWINGS

The disclosure will be described and explained with additional specificity and detail with the accompanying figures in which:

FIG. 1, illustrates a block diagram of a traditional First-in, First-out (FIFO)-based Wake-up Receiver (WuRX) 100 which rely on a clock signal (CLK) to propagate data (Data In) between memory blocks, in accordance with prior art.

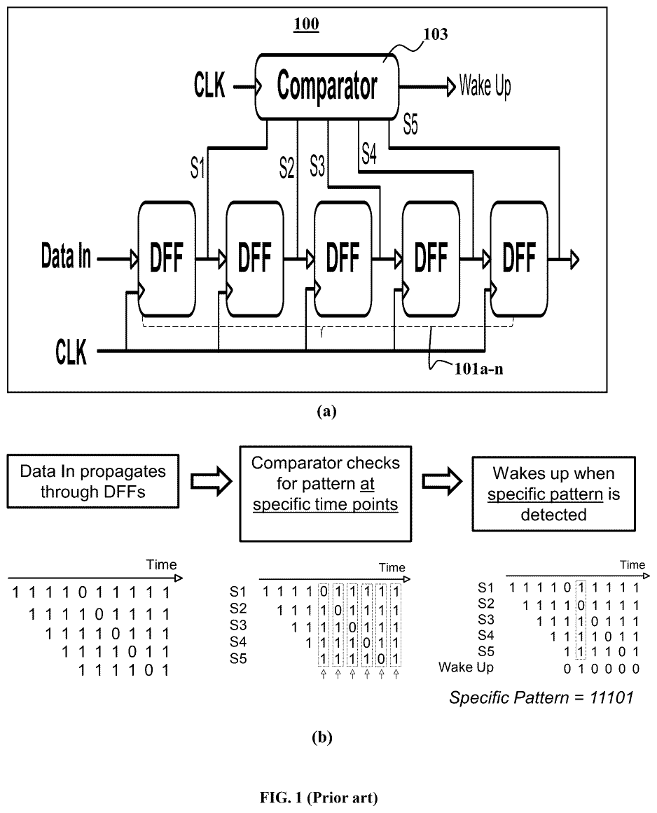

FIG. 2 illustrates an exemplary environment for energy efficient clockless wake-up receiver with dynamic clock generation in Body Area Networks (BAN) using a Human Body Communication (HBC) network, in accordance with an embodiment of the present disclosure.

FIG. 3 illustrates a schematic representation of the wake-up receiver unit, as shown in FIG. 2, in accordance with an embodiment of the present disclosure.

FIG. 4 illustrates a schematic representation of one or more primary delay cells, as shown in FIG. 3, in accordance with an embodiment of the present disclosure.

FIG. 5 illustrates a representation of a phase detector module for adjusting delay of the one or more parallel intermediate bitstreams to match a clock period associated with the one or more intermediate signals with a clock period of the one or more input signals by automatically tuning a delay value of the one or more primary delay cells, in accordance with an embodiment of the present disclosure.

FIG. 6 illustrates a representation of the phase detector module for validating tuning operation of the one or more primary delay cells, as shown in FIG. 2, in accordance with an embodiment of the present disclosure.

FIG. 7 illustrates a representation of regenerating the wake-up signal based on the delayed version of the interrupt signal and the original wake up signal, in accordance with an embodiment of the present disclosure.

FIG. 8 illustrates a schematic representation of a clock generation unit for switching to a clock recovery mode for extracting a clock from the one or more modulated data streams, in accordance with an embodiment of the present disclosure.

FIG. 9 illustrates a representation of switching operation of the clock generation unit between DLL mode and free-running mode, in accordance with an embodiment of the present disclosure.

FIG. 10 illustrates a representation of synchronizing the clock frequency of the clock generation unit to the carrier clock frequency of the one or more modulated data streams, when the one or more modulated data streams associated with the one or more input signals corresponds to the primary baseband logic value, in accordance with an embodiment of the present disclosure.

FIG. 11 illustrates a representation of Phase Locked Loop (PLL)-Delay Locked Loop (DLL) transition of the clock recovery unit, in accordance with an embodiment of the present disclosure.

FIG. 12 illustrates a schematic representation of the communication system, as shown in FIG. 2, in accordance with an embodiment of the present disclosure.

FIG. 13 illustrates a schematic representation of the WuRx, as shown in FIG. 12, in accordance with an embodiment of the present disclosure.

FIG. 14 illustrates a schematic representation of the ULP clock recovery unit, as shown in FIG. 12, in accordance with an embodiment of the present disclosure.

FIG. 15 illustrates a representation of the oscilloscope-captured waveform of the clockless WuRX and over the-channel clock recovery unit, as shown in FIG. 12, in accordance with an embodiment of the present disclosure.

FIG. 16 illustrates a representation of the comparison table illustrating comparison between wake up receiver of existing systems, and WuRX, as shown in FIG. 12, in accordance with an embodiment of the present disclosure.

FIG. 17 illustrates an exemplary flow chart depicting a communication method for energy efficient clockless wake-up receiver with dynamic clock generation in Body Area Networks (BAN) using a Human Body Communication (HBC) network.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show those specific details that are pertinent to understanding the embodiments of the present disclosure so as not to obscure the figures with details that will be readily apparent to those skilled in the art having the benefit of the description herein.

### DETAILED DESCRIPTION

For simplicity and illustrative purposes, the present disclosure is described by referring mainly to examples thereof. The examples of the present disclosure described herein may be used together in different combinations. In the following description, details are set forth in order to provide an understanding of the present disclosure. It will be readily apparent, however, that the present disclosure may be practiced without limitation to all these details. Also, throughout the present disclosure, the terms “a” and “an” are intended to denote at least one of a particular element. The terms “a” and “an” may also denote more than one of a particular element. As used herein, the term “includes” means includes but not limited to, the term “including” means including but not limited to. The term “based on” means based at least in part on, the term “based upon” means based at least in part upon, and the term “such as” means such as but not limited to. The term “relevant” means closely connected or appropriate to what is being performed or considered.

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration”. Any embodiment or implementation of the present subject matter described herein as “exemplary” is not necessarily to be construed as preferred or advantageous over other embodiments. The terms “comprise”, “comprising”, or any other variations thereof, are intended to cover a non-exclusive inclusion, such that one or more devices or sub-systems or elements or structures or components preceded by “comprises... a” does not, without more constraints, preclude the existence of other devices, sub-systems, additional sub-modules. Appearances of the phrase “in an embodiment”, “in another embodiment”, “in an exemplary embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are and not intended to be limiting. A computer system (standalone, client, or server, or computer-implemented system) configured by an application may constitute a “module” (or “subsystem”) that is configured and operated to perform certain operations. In one embodiment, the “module” or “subsystem” may be implemented mechanically or electronically, so a module includes dedicated circuitry or logic that is permanently configured (within a special-purpose processor) to perform certain operations. In another embodiment, a “module” or a “subsystem” may also comprise programmable logic or circuitry (as encompassed within a general-purpose processor or other programmable processor) that is temporarily configured by software to perform certain operations. Accordingly, the term “module” or “subsystem” should be understood to encompass a tangible entity, be that an entity that is physically constructed permanently configured (hardwired) or temporarily configured (programmed) to operate in a certain manner and/or to perform certain operations described herein.

Embodiments described herein provide a communication system and method for energy efficient clockless wake-up receiver with dynamic clock generation in Body Area Networks (BAN) using a Human Body Communication (HBC) network. The communication system comprises a wake-up receiver unit configured to operate in a constant active low-power mode for constantly listening to one or more input signals received from a transmitter, in which the wake-up receiver unit may operate in the constant low-power activated mode using leakage power. Further, the communication system comprises an intermittently operation unit connected to the wake-up receiver unit, in which the intermittently operation unit further comprises a clock generation unit configured to switch to a clock recovery mode for extracting a clock from the one or more modulated data streams. In an embodiment, the clock generation unit may switch to a clock maintained mode, for maintaining a clock frequency during absence of the one or more modulated data streams, in which in the clock recovery mode, the clock generation unit may be configured to extract and recover a desired carrier clock frequency from the one or more modulated data streams. Further, in an embodiment, in the clock maintained mode, the clock generation unit may be configured to preserve a recovered clock frequency to provide a stable reference for system blocks in the absence of the one or more modulated data streams.

In an embodiment, the communication system of the present disclosure introduces a novel clock-less wake-up receiver (WuRX) that operates at leakage power during idle states and a clock recovery unit capable of extracting the clock from on-off keying (OOK) modulated data streams without an external reference. The present disclosure replaces clocked components with analog delay cells and combinational logic, enabling low-latency wake-up functionality with minimal power draw. A double correlation mechanism ensures accurate wake-up code detection while preventing false triggering. The clock recovery unit combines Delay-Locked Loop (DLL) and Phase-Locked Loop (PLL) techniques for rapid and stable start-up synchronization, achieving start-up times under 80 μs. This approach significantly reduces listening power and start-up energy, advancing the state of ULP communication systems.

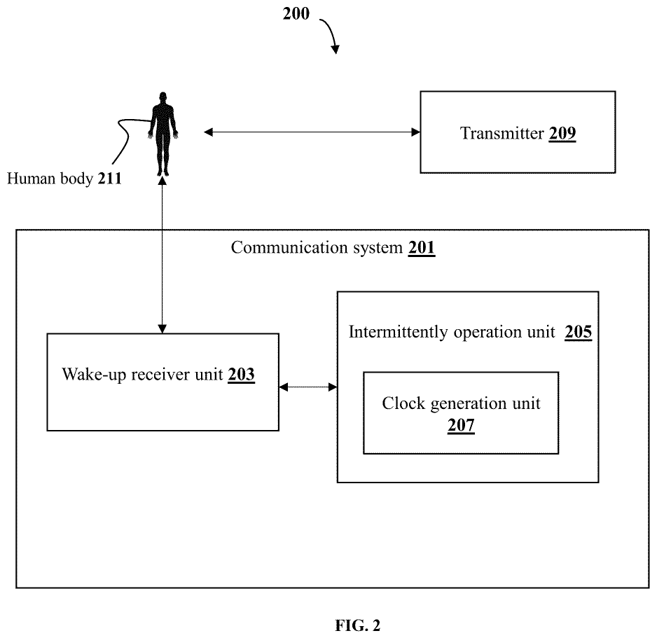

Referring now to the drawings, and more particularly to FIG. 2 through FIG. 17, where similar reference characters denote corresponding features consistently throughout the figures, there are shown preferred embodiments, and these embodiments are described in the context of the following exemplary system and/or method.

FIG. 2 illustrates an exemplary environment for energy efficient clockless wake-up receiver with dynamic clock generation in Body Area Networks (BAN) using a Human Body Communication (HBC) network, in accordance with an embodiment of the present disclosure.

As illustrated in FIG. 2, the exemplary environment 200 may include a communication system 201. Further, the communication system 201 may comprise a wake-up receiver unit 203, and an intermittently operation unit 205 connected to the wake-up receiver unit 203. Further, the intermittently operation unit 205 may comprise a clock generation unit 207.

In an embodiment, the wake-up receiver unit 203 may be configured to operate in a constant active low-power mode for constantly listening to one or more input signals received from a transmitter 209, in which the wake-up receiver unit 203 may operate in the constant low-power activated mode using leakage power. In an embodiment, the wake-up receiver unit 203 may receive one or more input signals from the transmitter 209 using a communication medium such as for example, but not limited to, a human body 211, as shown in FIG. 2. For example, the one or more input signals may include, but not limited to digital signals. Further, in an embodiment, the wake-up receiver unit 203, and the transmitter 209 may include, for example, but not limited to, a smartphone, a mobile phone, a personal digital assistant, a tablet computer, a tablet computer, a wearable device, a computer, a laptop computer, an Augmented Reality/Virtual Reality (AR/VR) device, Internet Of Things (IoT) device, a camera, any other device, and the combination thereof.

In an embodiment, the clock generation unit 207 may be configured to switch to a clock recovery mode for extracting a clock from the one or more modulated data streams, and in which the clock generation unit 207 may switch to a clock maintained mode, for maintaining a clock frequency during absence of the one or more modulated data streams. In an embodiment, in the clock recovery mode, the clock generation unit 207 may be configured to extract and recover a desired carrier clock frequency from the one or more modulated data streams, and in the clock maintained mode, the clock generation unit 207 may be configured to preserve a recovered clock frequency to provide a stable reference for system blocks in the absence of the one or more modulated data streams.

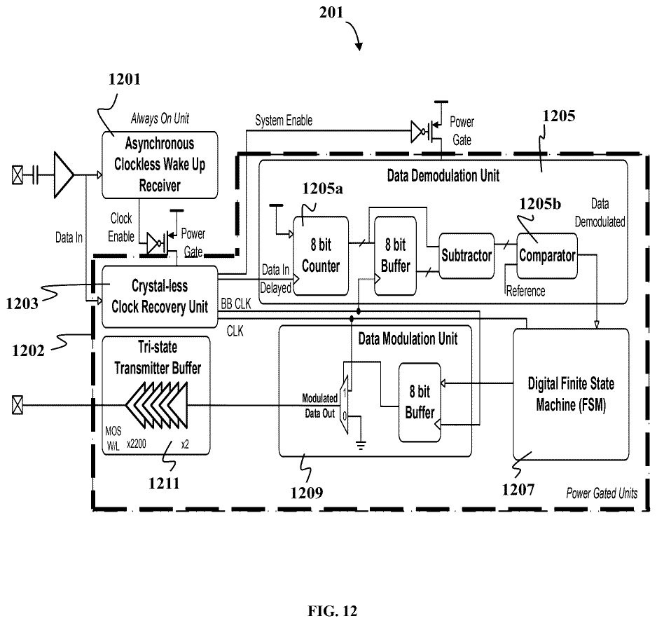

In an embodiment, the intermittently operation unit 205 is not restricted to comprise only the clock generation unit 207. However, the other one or more components present in the intermittently operation unit 205 as illustrated and explained in FIG. 12.

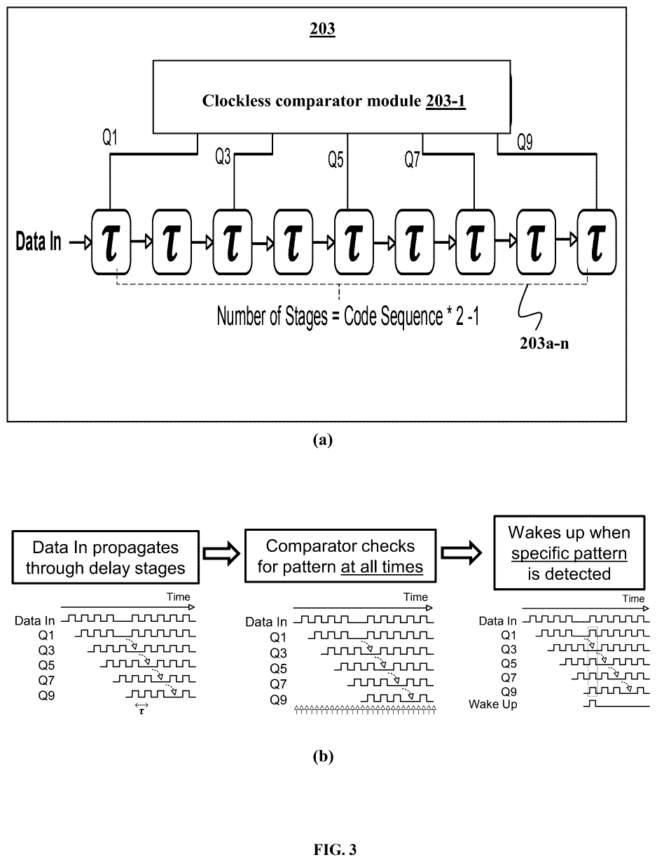

FIG. 3 illustrates a schematic representation of the wake-up receiver unit 203, as shown in FIG. 2, in accordance with an embodiment of the present disclosure.

In an embodiment, the wake-up receiver unit 203 may comprise one or more primary delay cells 203a-n, and a clockless comparator module 203-1.

In an embodiment, the one or more primary delay cells 203a-n may be configured to receive one or more input signals from one or more data sources through a communication medium. In an embodiment, the one or more input signals may comprise at least one or more modulated data streams corresponding to one or more modulation techniques. Further, in an embodiment, the one or more modulation techniques may comprise at least, for example, but not limited to, a On-Off Keying (OOK) modulation. For example, the one or more input signals may include, but not limited to digital signals. Further, in an embodiment, the one or more data sources may include, for example, but not limited to, a smartphone, a mobile phone, a personal digital assistant, a tablet computer, a tablet computer, a wearable device, a computer, a laptop computer, an Augmented Reality/Virtual Reality (AR/VR) device, Internet Of Things (IoT) device, a camera, any other device, and the combination thereof. Moreover, in an embodiment, the communication medium may include, for example, but not limited to, a human body 211 (as shown in FIG. 2).

Further, the one or more primary delay cells 203a-n may form a delay chain by serially connecting the one or more primary delay cells 203a-n, in which the delay chain may be configured to convert a serial data of the one or more input signals into one or more parallel intermediate bitstreams. In an embodiment, each of the one or more primary delay cells 203a-n may be configured to generate the one or more parallel intermediate bitstreams comprising at least a half-carrier-period delayed version of a preceding delay cell associated with each of the one or more primary delay cells 203a-n.

Further, the one or more primary delay cells 203a-n may be configured to generate one or more intermediate signals, based on the generated one or more parallel intermediate bitstreams.

Furthermore, the one or more primary delay cells 203a-n may adjust delay of the one or more parallel intermediate bitstreams to match a clock period associated with the one or more intermediate signals with a clock period of the one or more input signals by automatically tuning a delay value of the one or more primary delay cells 203a-n, in which each of the one or more primary delay cells 203a-n may be tuned to a plurality of fractions of a clock period of one or more carrier signals associated with the one or more modulated data streams. For example, the one or more primary delay cells 203a-n may be tuned to half a clock period of one or more carrier signals.

Subsequently, the one or more primary delay cells 203a-n may be configured to validate tuning operation of the one or more primary delay cells 203a-n, by identifying a mismatch between a phase value and a frequency value of the one or more intermediate signals, and the one or more input signals.

In an embodiment, the clockless comparator module 203-1 may be configured to compare the one or more parallel intermediate bitstreams of the generated one or more intermediate signals, with a predefined code pattern, and generate a wake-up signal for triggering an active state upon determining that the one or more parallel intermediate bitstreams match with the predefined code pattern.

In an embodiment, as shown in (a) of FIG. 3, the one or more primary delay cells 203a-n may be configured to receive one or more input signals (Data In) from one or more data sources through a communication medium. In an embodiment, the one or more input signals may comprise at least one or more modulated data streams corresponding to one or more modulation techniques. Further, in an embodiment, the one or more modulation techniques may comprise at least, for example, but not limited to, a On-Off Keying (OOK) modulation. For example, the one or more input signals may include, but not limited to digital signals. Further, in an embodiment, the one or more data sources may include, for example, but not limited to, a smartphone, a mobile phone, a personal digital assistant, a tablet computer, a tablet computer, a wearable device, a computer, a laptop computer, an Augmented Reality/Virtual Reality (AR/VR) device, Internet Of Things (IoT) device, a camera, any other device, and the combination thereof. Moreover, in an embodiment, the communication medium may include, for example, but not limited to, a human body 211 (as shown in FIG. 2).

Further, the one or more primary delay cells 203a-n may form a delay chain by serially connecting the one or more primary delay cells 203a-n, in which each of the one or more primary delay cells 203a-n may be configured to generate one or more parallel intermediate bitstreams (Q1, Q3, Q5, Q7, Q9) comprising at least a half-carrier-period delayed version of a preceding delay cell associated with each of the one or more primary delay cells 203a-n. For example, the output bit Q3 may comprise half-carrier-period delayed version of the output bit Q1.

Further, the one or more primary delay cells 203a-n may be configured to generate one or more intermediate signals, based on the generated one or more parallel intermediate bitstreams (Q1, Q3, Q5, Q7, Q9).

Furthermore, the one or more primary delay cells 203a-n adjust delay of the one or more parallel intermediate bitstreams (Q1, Q3, Q5, Q7, Q9) to match a clock period associated with the one or more intermediate signals with a clock period of the one or more input signals by automatically tuning a delay value of the one or more primary delay cells 203a-n, in which each of the one or more primary delay cells 203a-n may be tuned to a plurality of fractions of a clock period of one or more carrier signals associated with the one or more modulated data streams. For example, the one or more primary delay cells 203a-n may be tuned to half a clock period of one or more carrier signals. Further, in an embodiment, the one or more primary delay cells 203a-n may be tuned simultaneously.

Subsequently, the one or more primary delay cells 203a-n may be configured to validate tuning operation of the one or more primary delay cells 203a-n, by identifying a mismatch between a phase value and a frequency value of the one or more intermediate signals (also hereafter referred as intermediate signals (Q1, Q3, Q5, Q7, Q9)), and the one or more input signals (Data In).

In an embodiment, the clockless comparator module 203-1 may be configured to compare the one or more parallel intermediate bitstreams (Q1, Q3, Q5, Q7, Q9) of the generated one or more intermediate signals, with a predefined code pattern, and generate a wake-up signal upon determining that the one or more parallel intermediate bitstreams (Q1, Q3, Q5, Q7, Q9) match with the predefined code pattern.

In an embodiment, as shown in (a) of FIG. 3, the clock-less design of the wake-up receiver unit 203 may replace the clocked comparators (as disclosed in background) with combinational circuit-based comparators such as for example, but not limited to, the clockless comparator module 203-1. Further, the clocked memory blocks such as DFFs, (as disclosed in background) may be replaced with analog delay cells such as for example, but not limited to, the primary delay cells 203a-n, featuring adjustable delays. By tuning each of the primary delay cells 203a-n to half a carrier clock period and arranging them in a chain, data (Data In) propagates through the chain in a manner similar to the DFFs, (as disclosed in background). Moreover, the clockless comparator module 203-1 may evaluate the one or more parallel intermediate bitstreams (Q1, Q3, Q5, Q7, Q9) of the against a predefined code pattern and may generate a wake-up signal only when a match is detected. For example, as shown in (b) of FIG. 3, when the one or more parallel intermediate bitstreams (Q1, Q3, Q5, Q7, Q9) match with the predefined code pattern, the clockless comparator module 203-1 may generate a wake up signal.

In an embodiment, the wake-up receiver unit 203 may continuously monitor incoming one or more input signals from the transmitter 209 by remaining in a constant power on and listening mode. Further, the wake-up receiver unit 203 may operate in the listening mode, during an absence of data and until the one or more input signals are received from the transmitter 209, and remain in leakage power mode while actively processing the one or more input signals received from the transmitter 209.

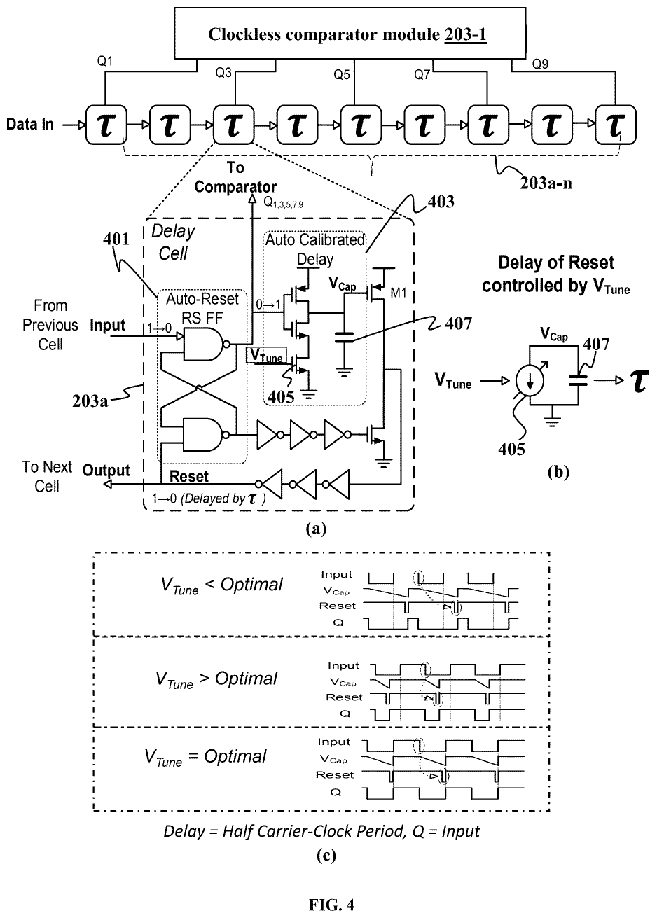

FIG. 4 illustrates a schematic representation of one or more primary delay cells 203a-n, as shown in FIG. 3, in accordance with an embodiment of the present disclosure.

In an embodiment, the one or more primary delay cells 203a-n may be configured to determine a phase difference between one or more input bits associated with the one or more input signals (Data In), and the one or more parallel intermediate bitstreams (Q1, Q3, Q5, Q7, Q9), using a phase detector module (not shown). Further, the one or more primary delay cells 203a-n may compare the phase difference with a pre-defined value, and adjust a delay period of the one or more parallel intermediate bitstreams (Q1, Q3, Q5, Q7, Q9) associated with the one or more intermediate signals to match with the one or more modulated data streams based on the compared phase difference by automatically tuning a phase and a frequency of the one or more parallel intermediate bitstreams (Q1, Q3, Q5, Q7, Q9) to match with the phase and frequency value of the one or more modulated data streams.

In an embodiment, to adjust the delay period of the one or more parallel intermediate bitstreams (Q1, Q3, Q5, Q7, Q9) associated with the one or more intermediate signals to match with the one or more modulated data streams based on the compared phase difference, the one or more primary delay cells 203a-n such as, but not limited to, a primary delay cell 203a (also hereafter referred as the one or more primary delay cells 203a-n) may comprise a combinational circuit 401, as shown in (a) of FIG. 4, configured to output a half-carrier-clock period delayed version of the one or more input signals (Data in) by generating a reset signal, based on activation of a set signal with a defined time period, In an embodiment, the reset signal may correspond to resetting operation of the one or more primary delay cells 203a-n. Further, an auto-calibrated delay unit 403 may be coupled to the combinational circuit 401, in which the auto-calibrated delay unit 403 may be configured to modify tuning voltages of one or more current sources 405 associated with the auto-calibrated delay unit 403, with respect to an optimal value. Further, the auto-calibrated delay unit 403 may modulate a discharge rate of one or more capacitors 407 associated with the auto-calibrated delay unit 403, based on the modified tuning voltages. Furthermore, the auto-calibrated delay unit 403 may be configured to adjust a delay timing of the reset signal, based on the modulated discharge rate, and adjust the delay period (Q1, Q3, Q5, Q7, Q9) of the one or more parallel intermediate bitstreams associated with the one or more intermediate signals, based on the adjusted delay timing of the reset signal. In an embodiment, the delay timing of the reset signal may correspond to a delay between the set signal, and the reset signal.

In an embodiment, the one or more primary delay cells 203a-n may comprise a basic reset-set flip-flop (RS FF) and a combinational circuit 401 designed to generate a reset signal whenever the set signal is briefly activated. The reset signal may serve as the input to the set signal of the subsequent delay cell. To ensure the reset signal is delayed so that the one or more parallel intermediate bitstreams (Q1, Q3, Q5, Q7, Q9) matches the pulse width of the one or more modulated data streams, an auto-calibrated delay unit 403 composed of one or more current sources such as, for example, but not limited to, an NMOS-based current source and one or more capacitors 407 may be added to the reset signal chain.

In an embodiment, the driving strength of the one or more current sources 405 may be controlled by a voltage, VTune (also referred as tuning voltages (VTune)), in which the tuning voltages (VTune) may modulate the discharge rate of one or more capacitors 407 (VCap), as shown in (b) of FIG. 4. Specifically, when VTune is higher, the NMOS transistor in the one or more current sources 405 may have a higher Vgs, resulting in greater current driving strength and a faster capacitor discharge. Conversely, a lower VTune may reduce the current driving strength, leading to a slower discharge of the one or more capacitors 407 (VCap).

In an embodiment, (c) of FIG. 4 illustrates how VTune affects the delay of the one or more primary delay cells 203a-n by influencing the discharge rate of one or more capacitors 409 407 (VCap), thereby adjusting the timing of the reset signal and the pulse width of the one or more parallel intermediate bitstreams (Q1, Q3, Q5, Q7, Q9). For example, as shown in (b) of FIG. 4, when VTune is set to an optimal value, the one or more parallel intermediate bitstreams (Q1, Q3, Q5, Q7, Q9) precisely may replicate the pulse width of the one or more input signals (Data In), with the pulse width of the reset signal generated exactly at the rising edge of the one or more input signals (Data In).

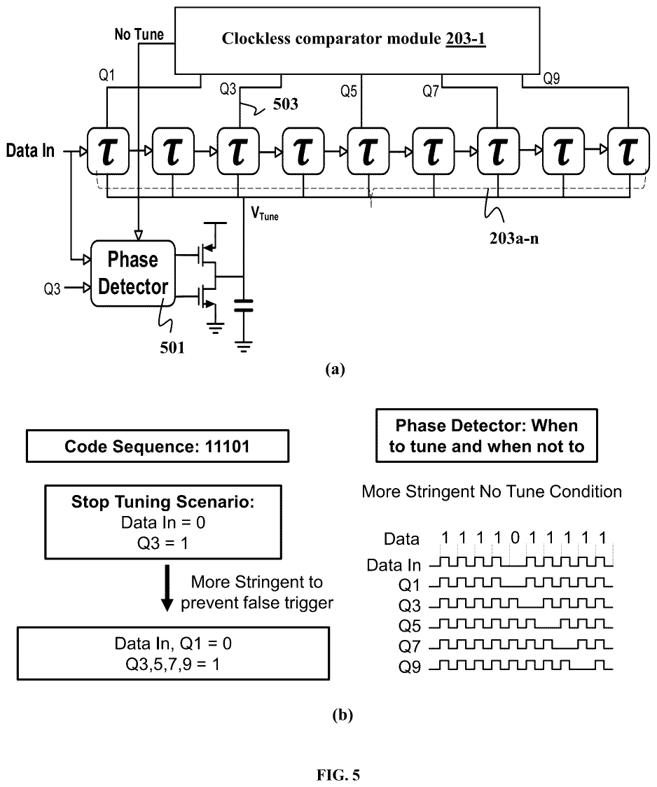

FIG. 5 illustrates a representation of a phase detector module 501 for adjusting delay of the one or more parallel intermediate bitstreams to match a clock period associated with the one or more intermediate signals with a clock period of the one or more input signals by automatically tuning a delay value of the one or more primary delay cells 203a-n, in accordance with an embodiment of the present disclosure.

In an embodiment, the one or more primary delay cells 203a-n may be configured to determine a phase difference between one or more input bits associated with the one or more input signals (Data In), and the one or more parallel intermediate bitstreams (Q1, Q3, Q5, Q7, Q9), using the phase detector module 501. Further, the phase detector module 501 may adjust a delay period of the one or more parallel intermediate bitstreams (Q1, Q3, Q5, Q7, Q9) associated with the one or more intermediate signals to match with the one or more modulated data streams based on the compared phase difference by automatically tuning a phase and a frequency of the one or more parallel intermediate bitstreams (Q1, Q3, Q5, Q7, Q9) to match with the phase and frequency value of the one or more modulated data streams.

In an embodiment, to achieve automatic tuning of the one or more primary delay cells 203a-n, the phase detector module 501 is employed, as shown in (a) of FIG. 5. The phase detector module 501 may comprise two inputs, in which the phase detector module 501 may compare the phase difference between the two inputs to determine whether to add or remove a small amount of charge to adjust the VTune. Specifically, if the one or more intermediate signals (Q1, Q3, Q5, Q7, Q9) lags behind the one or more input signals (Data In), the phase detector module 501 may increase VTune to reduce the delay. Conversely, if the one or more intermediate signals (Q1, Q3, Q5, Q7, Q9) leads the reference, the phase detector module 501 may decrease the VTune to increase the delay.

In an embodiment, by adjusting the VTune, the phase detector module 501 may modify pulse width of the one or more intermediate signals (Q1, Q3, Q5, Q7, Q9) and the timing of the one or more intermediate signals (Q1, Q3, Q5, Q7, Q9).

For example, the phase detector module 501 may continuously monitor the phase relationship (also referred as phase difference) between a input signal (Data In) and an intermediate signal (Q3) from the third analog delay cell 503 in the chain of the one or more primary delay cells 203a-n, providing feedback to iteratively tune VTune until the phase difference is minimized. This feedback mechanism may ensure that the delay introduced by the one or more primary delay cells 203a-n matches the desired timing, allowing the phase detector module 501 to converge to a locked state, in which the one or more intermediate signals (Q1, Q3, Q5, Q7, Q9) from the one or more primary delay cells 203a-n may align with the one or more input signals (Data In).

In an embodiment, in the phase detector module 501, any mismatch between the two inputs may result in an adjustment to the VTune. However, when the pre-defined code pattern may include a level-0 (e.g., 11101), this intentional mismatch should not trigger VTune adjustment. To address this, the combinational circuit 401, as shown in (a) of FIG. 4, may be implemented detect the specific condition of an input data being 0 and Q3 being 1, as shown in (b) of FIG. 5. To further prevent false triggering of this condition, a more stringent condition may be applied such as for example, but not limited to, Q3, Q5, Q7, and Q9 being equal to 1, while both the input data and Q1 may be equal 0. The combinational logic circuit 401 may evaluate the input data and Q1 against a predefined “no-tune” condition and may generate a stop signal to disable the tuning operation of the phase detector module 501. This may ensure that the phase detector module 501 does not incorrectly adjust VTune in response to intentional mismatches inherent to the code pattern.

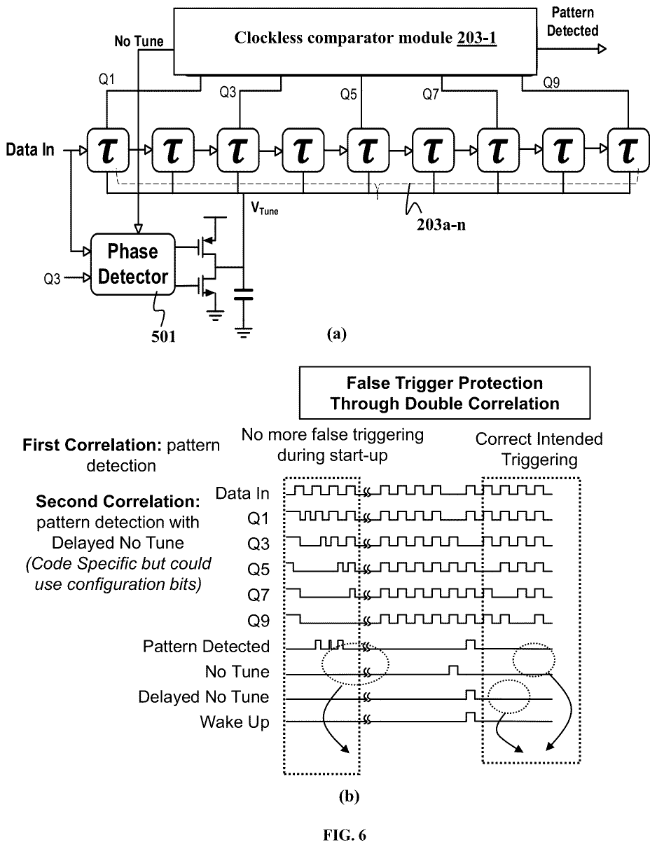

FIG. 6 illustrates a representation of the phase detector module 501 for validating tuning operation of the one or more primary delay cells 203a-n, as shown in FIG. 2, in accordance with an embodiment of the present disclosure.

In an embodiment, the communication system 201 may comprise a control unit (not shown) to determine whether a tuning is required to be performed on the one or more primary delay cells 203a-n based on the one or more parallel intermediate bitstreams (Q1, Q3, Q5, Q7, Q9). For example, the control unit may be, for example, but not limited to, integrated within the phase detector module 501.

Further, the control unit may generate an interrupt signal (also herein referred as no tune signal) for interrupting tuning operation of the one or more primary delay cells 203a-n based on the determination if the tuning is determined to be non-essential and disruptive to normal operation, in which the interrupt signal may be generated from the adjusted-delay for the one or more parallel intermediate bitstreams (Q1, Q3, Q5, Q7, Q9).

Furthermore, the control unit may determine an absence of the pre-defined code pattern in the generated one or more parallel intermediate bitstreams (Q1, Q3, Q5, Q7, Q9), and determine whether a false wake-up signal is generated during the absence of the pre-defined code pattern in the generated one or more parallel intermediate bitstreams (Q1, Q3, Q5, Q7, Q9).

Furthermore, the control unit may identify an occurrence of a false triggering event based on the determination, and compare a clock time period of the one or more parallel intermediate bitstreams (Q1, Q3, Q5, Q7, Q9) with a clock time period of the interrupt signal.

Moreover, the control unit may be configured to generate a delayed version of the interrupt signal based on the comparison, and regenerate the wake-up signal (also referred as pattern detected signal) based on the delayed version of the interrupt signal and the original wake up signal.

In an embodiment, the control unit may be configured to interrupt the tuning operation of the one or more primary delay cells 203a-n, based on the generated interrupt signal.

In an embodiment, as shown in (a) of FIG. 6, when VTune is actively being adjusted, or in the presence of spurious signals such as for example, but not limited to, noise signals and interference signals, the clockless comparator module 203-1 may falsely output a pattern-detected signal. To prevent such false triggering, the communication system 201 may implement a double-correlation mechanism for suppression. For example, the first correlation may involve the clockless comparator module 203-1 to check the one or more parallel intermediate bitstreams (Q1, Q3, Q5, Q7, Q9) against the pre-defined code pattern. Once a match is found, the clockless comparator module 203-1 may output the pattern-detected signal. The second correlation may leverage the timing relationship between the no-tune signal of the phase detector module 501 and the pattern-detected signal.

As illustrated in (b) of FIG. 6, for a code pattern of 11101, the no-tune signal associated with the logic-0 bit may always precede the pattern-detected signal by one clock period when the delays in the delay chain of the one or more primary delay cells 203a-n are properly calibrated. For other code patterns, the no-tune signal may precede the pattern-detected signal by one or more number of clock periods, in which the one or more number of clock periods may be adjusted using on-chip or on-board configuration bits.

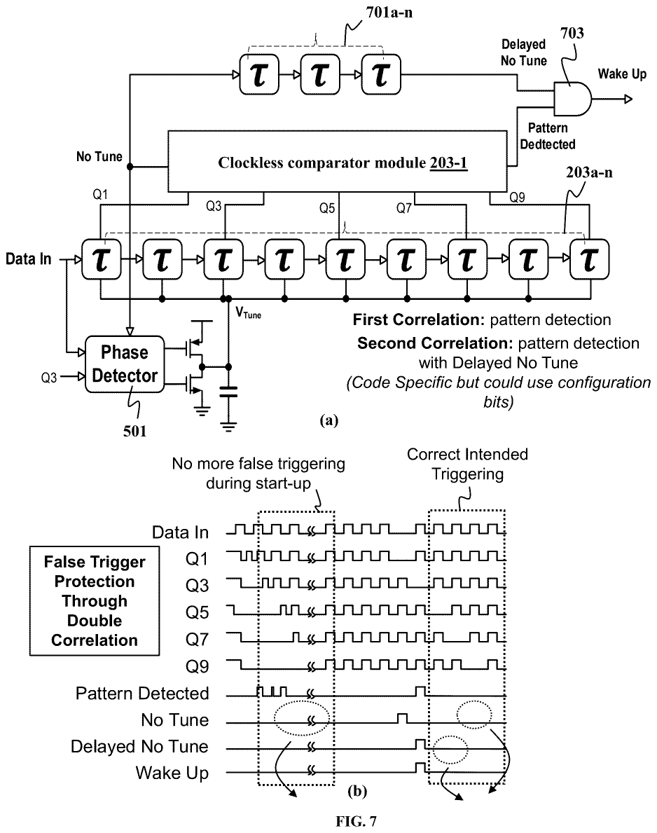

FIG. 7 illustrates a representation of regenerating the wake-up signal based on the delayed version of the interrupt signal (also hereafter referred as delayed no tune signal) and the original wake up signal, in accordance with an embodiment of the present disclosure.

In an embodiment, the control unit (not shown) may be configured to match an offset value of the interrupt signal with an offset value corresponding to the one or more parallel intermediate bitstreams (Q1, Q3, Q5, Q7, Q9), using one or more secondary delay cells 701a-n, as shown in (a) of FIG. 7, based on the adjusted delay value. Further, the control unit may perform AND logic operation on the interrupt signal and the one or more parallel intermediate bitstreams (Q1, Q3, Q5, Q7, Q9), based on matched offset values, and regenerate the wake-up signal, based on the performed AND logic operation. In an embodiment, the AND logic operation may be performed using a AND logic gate 703.

For example, to align the no-tune signal with the correct pattern-detected signal, a chain of the same analog delay cells such as for example, but not limited to, one or more secondary delay cells 701 may be used to delay the no-tune signal by the intended number of clock periods (matching the offset between the no-tune signal and the pattern-detected signal). Further, the AND logic gate 703 may then employed to output the wake-up signal only when both the no-tune signal and the pattern-detected signal are simultaneously logic 1 as shown in (b) of FIG. 7, ensuring reliable operation and eliminating false wake-ups.

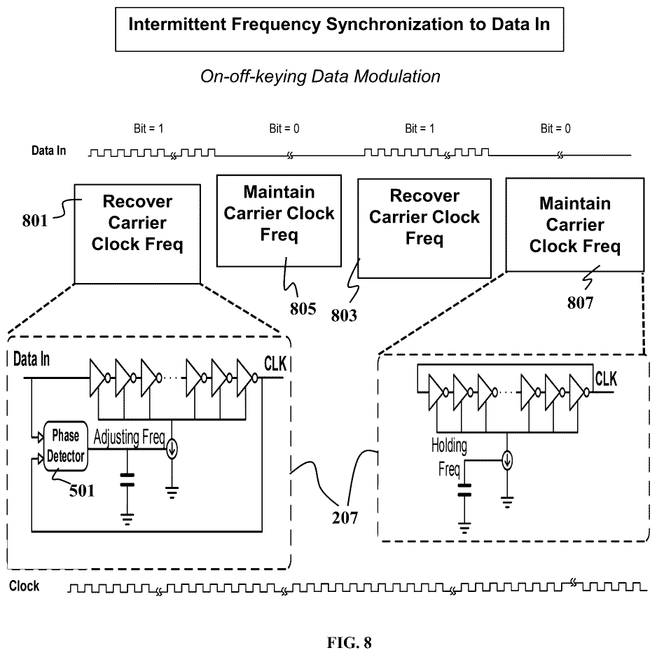

FIG. 8 illustrates a schematic representation of a clock generation unit 207 for switching to a clock recovery mode for extracting a clock from the one or more modulated data streams, in accordance with an embodiment of the present disclosure.

In an embodiment, the clock generation unit 207 may be configured to detect the presence of a carrier clock frequency in the one or more modulated data streams, and determine the logic state of the one or more modulated data streams based on the detected presence of the carrier clock frequency. Further, the clock generation unit 207 may recover the carrier clock frequency from the one or more modulated data streams, based on the determined logic state.

In an embodiment, to recover the carrier clock frequency from the one or more modulated data streams, based on the determined logic state, the clock generation unit 207 may be configured to synchronize a clock frequency of the clock generation unit 207 to the carrier clock frequency of the one or more modulated data streams, when the one or more modulated data streams associated with the one or more input signals corresponds to a primary baseband logic value. In an embodiment, the primary baseband logic value may include, for example, but not limited to, logic value 1. Furthermore, the clock generation unit 207 may recover the carrier clock frequency from the one or more modulated data streams, based on the synchronization.

For example, in an OOK-modulated data stream, the carrier clock may be present when the data input is logic 1 and may be absent when the data input is logic 0. To recover the carrier clock frequency, the clock generation unit 207 may intermittently synchronize the clock frequency to the data input stream when the input is logic 1 and maintain the recovered frequency when the input transitions to logic 0. This is achieved using a reconfigurable ring oscillator (RO)-based clock design such as an oscillator module (not shown) that may operate either as a delay-locked loop (DLL) or a free-running Ring Oscillator (RO).

In an embodiment, as shown in FIG. 8, the clock generation unit 207 may be configured to operate in a Delay-Locked Loop (DLL) mode, when the one or more modulated data streams associated with the one or more input signals corresponds to a primary baseband logic value. In an embodiment, the DLL mode may correspond to recovering the carrier clock frequency from the one or more input signals, and in which the primary baseband logic value may correspond to presence of the carrier clock frequency in the one or more input signals.

In an embodiment, the clock generation unit 207 may be configured to operate in a free-running mode, when the one or more modulated data streams associated with the one or more input signals corresponds to a secondary baseband logic value, in which the free-running mode may correspond to setting the recovered carrier clock frequency as a constant value. In an embodiment, the secondary baseband logic value may include at least, for example, but not limited to, logic 0. Further, in an embodiment, the secondary baseband logic value may correspond to absence of the carrier clock frequency in the one or more input signals (Data In).

For example, as shown in FIG. 8, the clock generation unit 207 switches to a clock maintained mode, for maintaining a clock frequency, as shown in blocks 801 and 803, during absence of the one or more modulated data streams. That is, in the clock recovery mode, the clock generation unit 207 may be configured to extract and recover a desired carrier clock frequency from the one or more modulated data streams, and in the clock maintained mode, as shown in blocks 805 and 807, the clock generation unit 207 may be configured to maintain a recovered clock frequency to provide a stable reference for system blocks in the absence of the one or more modulated data streams.

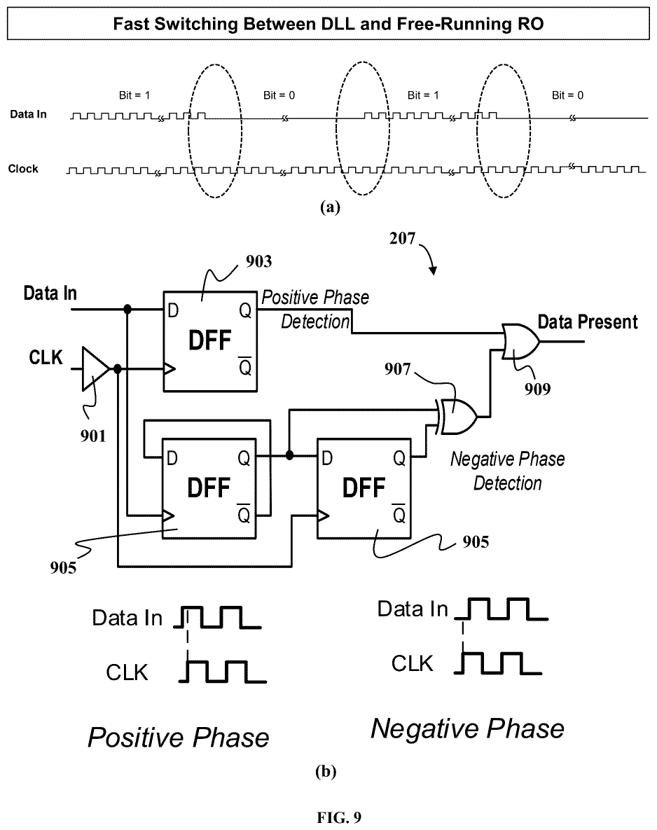

FIG. 9 illustrates a representation of switching operation of the clock generation unit 207 between DLL mode and free-running mode, in accordance with an embodiment of the present disclosure.

In an embodiment, (a) of FIG. 9 represents a timing diagram of switching operation of the clock generation unit 207 between DLL mode and free-running mode. In an embodiment, the clock generation unit 207 may comprise one or more flip flop units configured to switch the clock unit between the DLL mode, and the free-running mode. In an embodiment, the clock generation unit 207 may be configured to detect a positive phase difference value between the one or more input signals (Data In), and an output of a clock module 901 associated with the clock generation unit 207, using primary flip flop units 903. Further, the clock generation unit 207 may detect a negative phase difference value between the one or more input signals (Data In), and the output of the clock module 901 associated with the clock generation unit 207, using secondary flip flop units 905, as shown in (b) of FIG. 9. Furthermore, the clock generation unit 207 may determine presence of data in the one or more input signals (Data In) by performing a set of logic operations on output of one of the secondary flip flop units 905 and the primary flip flop units 903. Furthermore, the clock generation unit 207 may switch the clock generation unit 207 between the DLL mode, and the free-running mode, based on the determined one of a presence and absence of the data in the one or more input signals. For example, as shown in FIG. 9, the set of logic operations may include, for example, but not limited to, a XOR logic operation performed using a XOR logic gate 907, and an OR logic operation performed using an OR logic gate 909.

In an embodiment, fast switching between these the DLL mode and the free-running mode may be critical for maintaining stable operation of the clock generation unit 207. During the transition from logic 1 to logic 0, as shown in (a) of FIG. 9, fast switching may minimize unintended VTune adjustments, thereby preserving the oscillation frequency. Conversely, during the transition from logic 0 to logic 1, fast switching may ensure that the clock generation unit 207 may immediately enter the DLL mode upon detecting the first logic 1, allowing it to recalibrate the output frequency.

In an embodiment, to detect a positive phase difference between the data input (Data In) and the output of a clock module 901, a single DFF may be used, with a small delay added to the clock line to prevent metastability. For detecting a negative phase difference, two additional DFFs may be used. The outputs of these two DFFs may be XORed to form a data presence signal, to control the reconfiguration of the clock generation unit 207 between the DLL mode and the free-running mode.

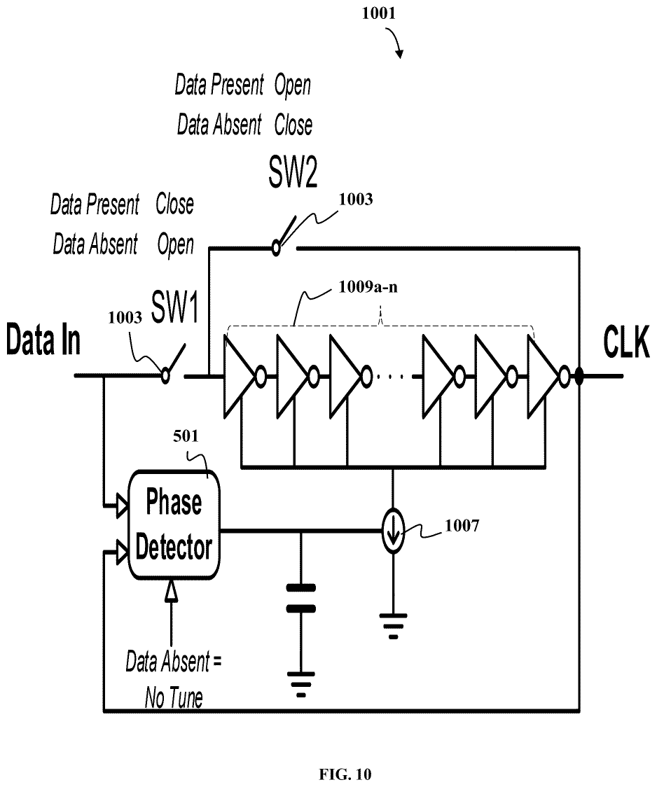

FIG. 10 illustrates a representation of synchronizing the clock frequency of the clock generation unit to the carrier clock frequency of the one or more modulated data streams, when the one or more modulated data streams associated with the one or more input signals corresponds to the primary baseband logic value, in accordance with an embodiment of the present disclosure.

In an embodiment, the clock generation unit 207 may comprise an oscillator module 1001 configured to determine if one or more primary switches 1003 associated with the oscillator module 1001 are closed, and if one or more secondary switches 1005 associated with the oscillator module 1001 are open. Further, the oscillator module 1001 may modify tuning voltages (VTune) of one or more current sources 1007 associated with the clock generation unit 207, with respect to an optimal value, in which the tuning voltages may be modified using the phase detector module 501. Further, the oscillator module 1001 may adjust a delay value of one or more inverters 1009a-n associated with the clock generation unit 207 based on the modified tuning voltages. In an embodiment, the phase detector module 501 may be configured to compare each input signal with an output of the oscillator module 1001 to adjust the delay of the one or more inverters 1009a-n. Finally, the oscillator module 1001 may synchronize the clock frequency of the clock generation unit 207 to the carrier clock frequency of the one or more modulated data streams, based on the adjusted delay value.

For example, when the one or more primary switches 1003 (SW1) are closed and the one or more secondary switches 1005 (SW2) are open, the oscillator module 1001 may take the data input (Data In) as reference. The delays between the one or more inverters 1009a-n may be adjusted similarly to the adjustment of delay in the one or more primary delay cells 203a-n in the wake-up receiver unit 203, using one or more current sources 1007, in which driving strength of the one or more current sources 1007 may be controlled by tuning voltages (VTune). In other words, VTune may be dynamically adjusted by the phase detector module 501, in which the phase detector module 501 may compare the data input signal (Data In) with an output of the oscillator module 1001.

In an embodiment, the oscillator module 1001 may be configured to determine if the one or more primary switches 1003 associated with the oscillator module 1001 of the clock generation unit 207 are open, and if the one or more secondary switches 1005 associated with the oscillator module 1001 of the clock generation unit 207 are closed. Further, the oscillator module 1001 may operate in a free-running mode, based on the determination, in which the free-running mode may correspond to a closed loop configuration of the oscillator module 1001. In an embodiment, the closed loop configuration may correspond to a direct connection between an input and an output of the oscillator module 1001, in which the direct connection may further correspond to a constant value of the input and the output for the oscillator module 1001. Furthermore, the oscillator module 1001 may generate a constant delay value for the one or more inverters 1009a-n associated with the clock generation unit 207, by terminating the tuning operation in the oscillator module 1001, and set the recovered carrier clock frequency as a constant value, based on the generated constant delay value for the one or more inverters 1009a-n.

For example, when the one or more primary switches 1003 (SW1) are open and the one or more secondary switches 1005 (SW2) are closed, the oscillator module 1001 may operate in free-running mode, using output of the oscillator module 1001 as the input to form a closed-loop design. In this mode, the phase detector module 501 may be suspended, and the tuning voltages (VTune) may remain unchanged, maintaining the same delay between the one or more inverters 1009a-n and thus the same oscillation frequency between the one or more inverters 1009a-n.

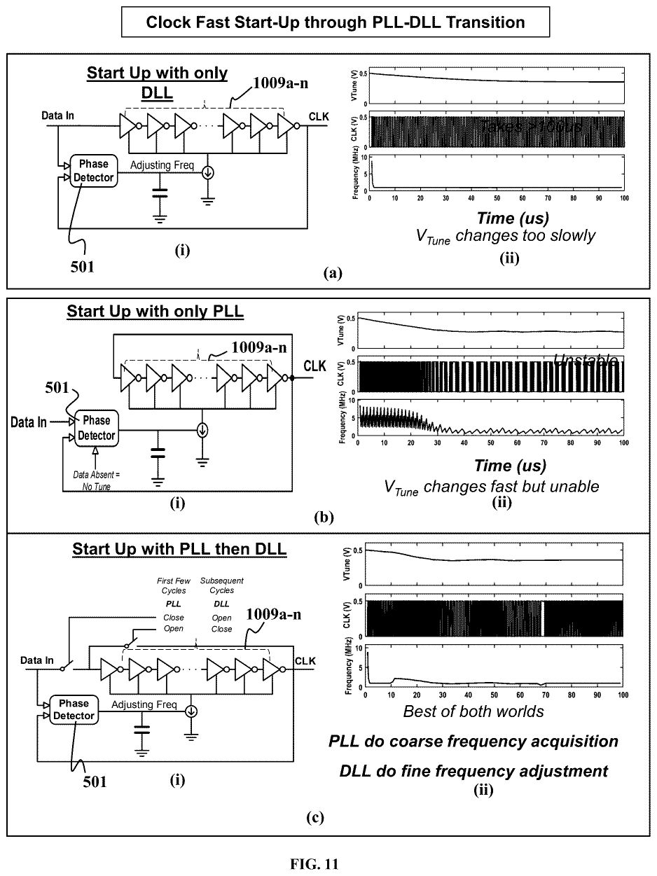

FIG. 11 illustrates a representation of Phase Locked Loop (PLL)-Delay Locked Loop (DLL) transition of the clock generation unit 207, in accordance with an embodiment of the present disclosure.

In an embodiment, the clock generation unit 207 may achieve fast frequency locking from start-up through a combined PLL-DLL transition. In an embodiment, the PLL mode, as shown in (i) of FIG. 11(b) may configure the oscillator module 1001 in a free-running mode, with the phase detector 501 enabled to continuously calibrate VTune by comparing the data input (Data In) with the output of the oscillator module 1001. In the PLL mode, the baud rate clock recovery may be inherently unstable, since the data input (Data In) and the output of the oscillator module 1001 may operate at the same frequency. However, the PLL mode may quickly converge VTune to an approximate value, as shown in (ii) of FIG. 11(b), due to the large adjustment steps driven by the significant phase differences between the data input (Data In) and the output of the oscillator module 1001.

In an embodiment, a pure DLL start-up, as shown in (i) of FIG. 11(a), may achieve a correct output frequency quickly, but the VTune adjustment being considerably slower, as shown in (ii) of FIG. 11(a). This is because, in DLL mode, the open-loop design may naturally align the output of the oscillator module 1001 with the data input (Data In), resulting in smaller phase differences between the data input (Data In) and the output of the oscillator module 1001, which may limit the ability of the phase detector 501 to adjust VTune rapidly. To optimize both start-up speed and VTune accuracy, the clock generation unit 207 may employ a hybrid approach, as shown in (i) of FIG. 11(c) using PLL mode for a few cycles, and allowing VTune to converge near the correct value quickly. The generation unit 207 may then switch to DLL mode, where finer adjustments may refine VTune to lock onto the carrier clock frequency accurately, as shown in (ii) of FIG. 11(c). This technique may enable a faster and more precise start-up, achieving frequency locking in less than at least, for example, but not limited to, 80 μs in the communication system 201 (with a carrier frequency of 1 MHz).

FIG. 12 illustrates a schematic representation of the communication system 201, as shown in FIG. 2, in accordance with an embodiment of the present disclosure.

In an embodiment, the communication system 201 may consist of a Ultra Low Power (ULP) and a low-latency asynchronous Wake-up Receiver (WuRX) 1201 (also hereafter referred as WuRX 1201), and an intermittently operation unit 1202. In an embodiment, intermittently operation unit 1202 may comprise a ULP clock recovery unit 1203, a digital data demodulation unit 1205, comprising a counter 1205a and a comparator 1205b to demodulate data, a digital Finite State Machine (FSM) 1207, an OOK data modulation unit 1209, and a transmitter tri-state driver 1211. The WuRX 1201, despite being clockless, may pass the input data stream through one or more delay stages, with each stage automatically tuned to a delay equal to half the carrier-clock-period. This design may convert the incoming serial bit pattern to multiple-parallel delay-adjusted bit streams on which a combinational circuit may operate without a clock, allowing the asynchronous WuRX 1201 to be triggered only by the correct bit pattern.

In an embodiment, the WuRX 1201 is similar to the wake-up receiver unit 203 of FIG. 2. Further, the ULP clock recovery unit 1203 is similar the clock generation unit 207 of FIG. 2. Moreover, the intermittently operation unit 1202 is similar to the intermittently operation unit 205 of FIG. 2.

In an embodiment, to enable ULP listening, instead of oversampling and Nyquist designs, a clockless asynchronous design of the WuRX 1201 may ensure that only leakage power is consumed while maintaining the wake-up capability. This may reduce the listening power consumption to just for example, but not limited to, 191.6nW. Moreover, the intermittently syncing clock recovery unit 1203 may operate by synchronizing to the intermittent OOK data, where the carrier frequency may be present during a bit ‘1’and maintaining the frequency during bit ‘0’.

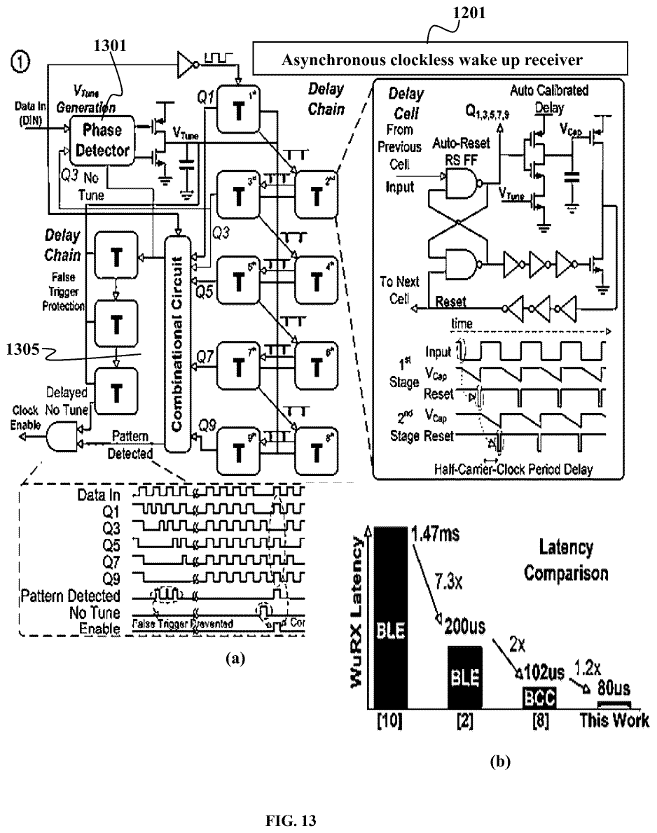

FIG. 13 illustrates a schematic representation of the WuRx 1201, as shown in FIG. 12, in accordance with an embodiment of the present disclosure.

In an embodiment, the data input (DIN), as shown in (a) of FIG. 13, may flow through at least, for example, but not limited to nine cascaded delay cells, in which each of the nine cascaded delay cells may be tuned to a half carrier-clock-period delay. The wake-up sequence matching may happen at the carrier-clock domain to achieve low latency. The design of the WuRX 1201 may be enhanced by incorporating an auto-tuning capability. Specifically, a phase detector (PD) 1301 may be implemented to adjust the delays of each cell through current starving by comparing the DIN with the delay chain third-stage output and controlling Vtune. In an embodiment, the PD 1301 is similar to phase detector module 501 of FIG. 5.

Within each cell, the input may be processed by a reset-set flip-flop 1303, in which the reset-set flip flop 1303 may automatically reset after a half-clock period by a self-generated reset pulse to allow sufficient Vcap rise time to VDD. After the 1st delay stage, the reset pulse may become the input to ripple-carry DIN to subsequent delay stages. Further, when the individual delay matches the half-clock period, all the Q's may represent an integer multiple of a half-clock-period delayed copy of DIN. After the delay auto-tuning and serial to parallel conversion, a combinational circuit 1305 may detect the correct bit sequence by comparing the outputs (Q1,3,5,7,9) with a 5-bit Barker code 11101. The level-0 in the code sequence may require a mechanism to prevent unintended delay tuning when the input is level-0 and Q3 is level-1. To address this, the combinational circuit 1305 may generate a no-tune signal to stop the PD when the input is level-0, with all outputs being level-1. A false-triggering protection circuit may be developed to enhance reliability further by delaying the no-tune signal by a clock period. The enable signal may only be triggered when the correct bit sequence and the delayed no-tune signal are detected together. This approach effectively may prevent spurious spikes and misalignments of outputs from falsely triggering the enable signal, which may otherwise occur during startup or with incorrect DIN sequences. Further, true negatives may be reduced by utilizing a wake-up sequence with repeated barker codes. In the presence of DIN, the WuRX 1201 may consume for example, but not limited to, 425.5 nW, which may be 105× lower than existing systems, as shown in (b) of FIG. 13.

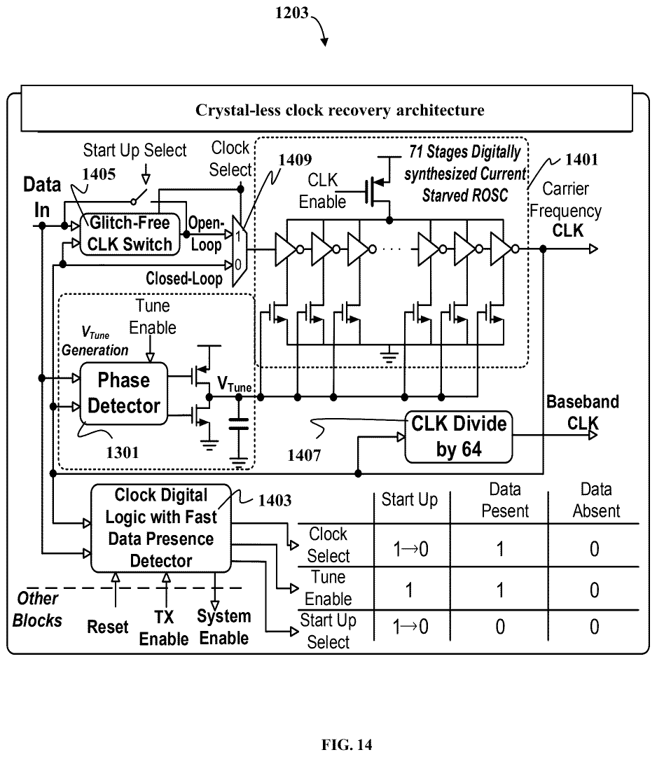

FIG. 14 illustrates a schematic representation of the ULP clock recovery unit 1203, as shown in FIG. 12, in accordance with an embodiment of the present disclosure.

In an embodiment, oversampling Clock Recovery (CR) techniques may suffer from increased complexity and power consumption despite being commonly employed for high accuracy and low jitter. To enhance energy efficiency, the clock recovery unit 1203 may implement a baud rate CR approach. The CR core may be for example, but not limited to, a 71-stage digitally-synthesized current-starved ring oscillator (ROSC) 1401 with a closed-loop and open-loop mode. In the closed-loop mode, the output of ROSC 1401 may provide feedback to input, whereas in the open-loop mode, the data input (DIN) may be directly fed into the ROSC 1401. The PD 1301 may adjust the oscillation frequency by varying the propagation delay of the ROSC current-starved inverter, through Vtune. To achieve a fast start-up and fast lock onto the carrier frequency, the PD 1301 may be enabled at start-up, and the ROSC 1401 may operate in open-loop mode for at least, for example, but not limited to, 10 clock cycles, followed by 1000 cycles in closed loop mode. This process may accelerate the frequency locking time to at least, for example, but not limited to, <80 us. After the start-up phase, the ROSC 1401 may sync to the carrier clock frequency whenever DIN is present by switching to open-loop mode with the PD 1301 enabled. When DIN is absent, the ROSC 1401 may maintain the open-loop oscillation frequency by switching back to closed-loop mode and disabling the PD 1301 to effectively hold the Vtune.

Further, a fast data presence detector 1403 may be implemented to identify positive and negative phase differences between DIN and the clock output, allowing instant switching between the two modes. Moreover, no tuning is required if no phase difference is detected between DIN and the clock.

In an embodiment, a glitch-free clock switch 1405 may ensure that the wake-up receiver unit 1201 may effectively handle the transition between low-power and active states, maintaining clock integrity, avoiding errors, and ensuring reliable operation of the communication system 201. Further, in the clock generation unit 1203, a clock divide-by-64 unit 1407 may play an essential role in managing the timing and frequency of signals in the low-power listening mode. In other words, the WuRX may be designed to listen for specific signals while operating in an ultra-low-power state. In such systems, power consumption needs to be minimized, and the WuRX 1201 may typically operate on a low-frequency clock. To conserve energy, the WuRX 1201 may not operate at the full system clock frequency when listening for the wake-up signal. The clock divide-by-64 unit 1407 may scale down the clock frequency, making the WuRX 1201 more power-efficient.

For example, if the system clock is running at 64 MHz, the clock divide-by-64 unit 1407 may output a 1 MHz clock. This lower clock speed may reduce power consumption in idle or waiting states.

In an embodiment, the multiplexer 1409 in the clock generation unit 1203 may switch between the different clock sources based on the current mode of the WuRX 1201. For example, when the WuRX is in the listening state, the multiplexer 1409 may select the low-frequency clock (e.g., 1 MHz). Upon detecting a wake-up signal and transitioning to an active state, the multiplexer 1409 may switch to the high-frequency system clock (e.g., 64 MHz).

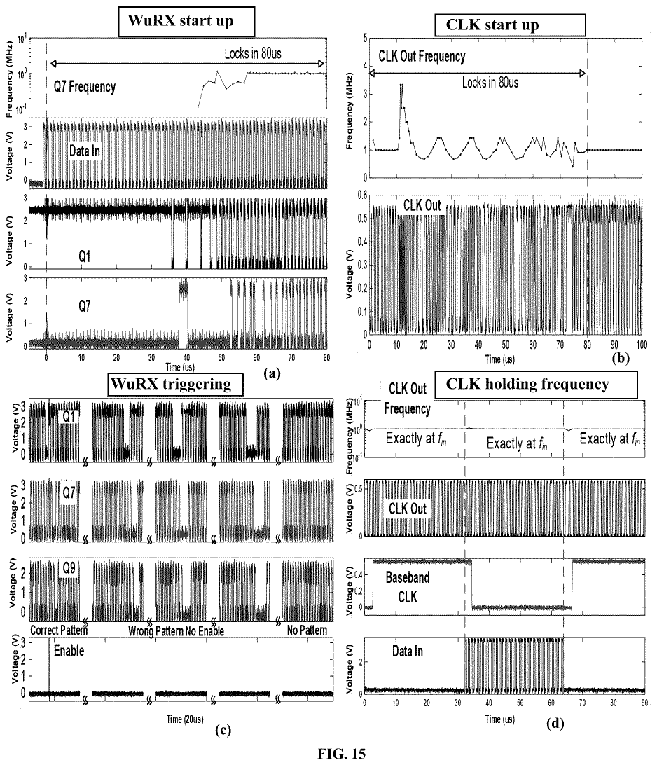

FIG. 15 illustrates a representation of the oscilloscope-captured waveform of the clockless WuRX 1201 and over the-channel clock recovery unit 1203, as shown in FIG. 12, in accordance with an embodiment of the present disclosure.

In an embodiment, as shown (a)-(d) of FIG. 15, for the WuRX 1201, the measured Q1 and Q7 signals may be displayed, demonstrating frequency locking onto the DIN frequency in for example, but not limited to, <80 us. Additionally, the data may be propagated sequentially from Q1 to Q7 and Q9, with the enable signal being sent out only when the correct bit pattern is detected. For the clock recovery unit 1203, the measured start-up waveform may show that the frequency converges to the 1 MHz DIN carrier frequency within 80 us. The intermittent synchronization capability may also be illustrated, with the clock frequency holding input frequency during the absence of DIN and locking to 1 MHz upon the presence of DIN. Moreover, by performing demodulation in the digital domain, an adjustable hysteresis mechanism may enable a clock frequency deviation tolerance of up to for example, but not limited to, 3.3%, enabling prolonged DIN absence. In contrast with conventional RF WuRXs, which prioritize sensitivity enhancement, this paper focuses on innovations in the time domain for asynchronous, the clockless WuRX 1201, may simultaneously achieve low latency and ULP along with intermittently syncing clock recovery suitable for wideband body channels.

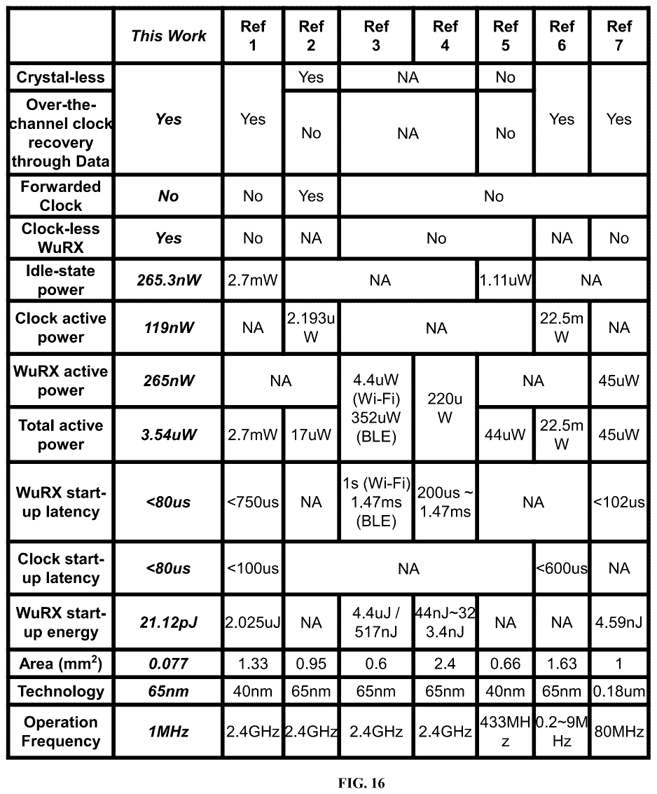

FIG. 16 illustrates a representation of the comparison table illustrating comparison between wake up receiver of existing systems, and WuRX 1201, as shown in FIG. 12, in accordance with an embodiment of the present disclosure.

In an embodiment, proposed design of the WuRX 1201 may achieve a listening power of for example, but not limited to, 191.6 nW>5× reduction compared to wake up receivers of existing systems, while maintaining a start-up latency of for example, but not limited to, <80 us, and requiring just 34 pJ of start-up energy, marking a significant improvement over the existing systems. Further, the crystal-less operation of the WuRX 1201 may be realized by intermittently syncing with the incoming data, achieving a clock start-up latency of <80 us, a 20% improvement over existing systems.

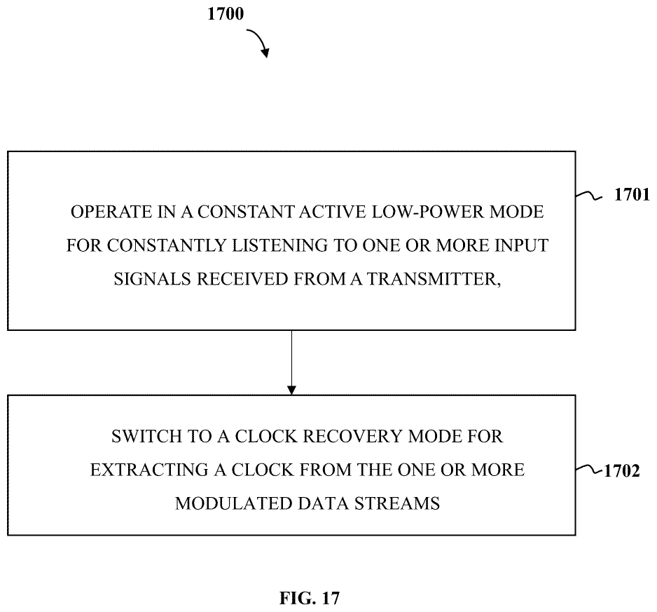

FIG. 17 illustrates an exemplary flow chart depicting a communication method for energy efficient clockless wake-up receiver with dynamic clock generation in Body Area Networks (BAN) using a Human Body Communication (HBC) network, in accordance with an embodiment of the present disclosure.

At step 1701, the method 1700 includes operating, by a wake-up receiver unit 203, in a constant active low-power mode for constantly listening to one or more input signals received from a transmitter, in which the wake-up receiver unit 203 may operate in the constant low-power activated mode using leakage power.

At step 1702, the method 1700 includes switching, by a clock generation unit 207, to a clock recovery mode for extracting a clock from the one or more modulated data streams, in which the clock generation unit 207 may switch to a clock maintained mode, for maintaining a clock frequency during absence of the one or more modulated data streams. In an embodiment, in the clock recovery mode, the clock generation unit 207 may be configured to extract and recover a desired carrier clock frequency from the one or more modulated data streams, and in the clock maintained mode, the clock generation unit 207 may be configured to preserve a recovered clock frequency to provide a stable reference for system blocks in the absence of the one or more modulated data streams.

The order in which the method 1700 is described is not intended to be construed as a limitation, and any number of the described method blocks may be combined or otherwise performed in any order to implement the method 1700 or an alternate method. Additionally, individual blocks may be deleted from the method 1700 without departing from the spirit and scope of the ongoing description. Furthermore, the method 1700 may be implemented in any suitable hardware, software, firmware, or a combination thereof, that exists in the related art or that is later developed. The method 1700 describes, without limitation, the implementation of the communication system 201 for energy efficient clockless wake-up receiver with dynamic clock generation in Body Area Networks (BAN) using a Human Body Communication (HBC) network. A person of skill in the art will understand that method 1700 may be modified appropriately for implementation in various manners without departing from the scope and spirit of the ongoing description.

In an embodiment, the present disclosure relates to ultra-low-power (ULP) communication systems, specifically to wake-up receivers (WuRX) and clock recovery units designed for energy-efficient operation in wearable devices and Internet of Things (IoT) applications. The present disclosure addresses the challenges of reducing idle power consumption, eliminating reliance on always-running clocks or external references, and achieving low latency and high responsiveness.

The present disclosure introduces a clock-less WuRX with innovative circuit designs and a clock recovery unit capable of synchronization from on-off keying (OOK) modulated data streams, providing significant advancements in energy efficiency, system integration, and operational versatility for energy-constrained applications.

The present disclosure introduces a clock-less wake-up receiver that consumes only leakage power during listening and a clock recovery unit capable of intermittently recovering the clock from an on-off keying (OOK) modulated data stream. Compared to existing techniques, the clock-less WuRX of the present disclosure offers significant advantages, including iso-latency power reduction, ultra-low listening power (e.g., 191.6 nW), and reduced start-up energy consumption.

The present disclosure describes a low-power communication device comprising a wake-up receiver (WuRX), and A clock generation unit. The low-power communication device has the capability of always-on listening, an example being a receiver that is always-on and actively listening to the incoming data. Further, the low-power communication device has the capability of instant responsiveness, an example being a transceiver that, when triggered, may respond to the trigger instantly (e.g., within 1 second). Further, the low-power communication device has the capability of low-power mode, an example being a mode where power consumption is substantially lower compared to the active mode.

The WuRX of the present disclosure comprises a First-in, first-out (FIFO) data streaming, where the first data to enter the unit is the first to exit, and FIFO data streaming progressing at the same data rate as the incoming data stream. Further, the WuRX has the ability to detect the presence of a specific code pattern in the incoming data stream, and the ability to wake up only upon detecting the specific code pattern. Furthermore, the WuRX has ability to maintain normal operation in the absence of a local active running clock, and a fast wake-up capability (<80 μs) from power-on or after long inactivity. Furthermore, the WuRX has the ability of extremely low active power consumption (≤265 nW), and extremely low listening power consumption when no data stream is present but the WuRX is operational, with power consumption down to leakage levels (<200 nW).

The WuRX of the present disclosure comprises a delay cell configured to take an input and output: (i) a delayed pulse, and (ii) a square wave. Further, the delay cell comprises a reset-set flip flop (RS FF) and a delay element, in which the RS FF can automatically reset itself into a stable state, with or without an input, in which the delay element controls the reset delay, and in which the delay element controls the time delay between the input and output. Further, the delay cell is configured to allow adjustment of the delay through a tuning voltage (VTune).

The WuRX of the present disclosure comprises a delay chain made of delay cells configured such that the delay cells are serially connected, with cell 1 connected to the data input, cell 2 to the output of cell 1, and so on. Further, the delay cells are configured such that each delay cell connects to the reset signal of the preceding cell. Further, the delay cells are configured such that each delay cell outputs a square wave signal (Q), with Q1 representing the input, Q2 representing a half-carrier-period delayed version of Q1, and so forth. Subsequently, the delay cells are configured such that if the specific code pattern has a length of n, the number of delay cells required is 2n-1 (e.g., a code pattern of length 5 requires 9 delay cells).

The WuRX of the present disclosure comprises an automatic adjustment mechanism for the delay of each individual delay cell, in which the adjustment mechanism comprises a phase detector. The phase detector takes two inputs such as the incoming data stream and an odd-numbered output from the delay chain.

The WuRX of the present disclosure comprises a stop-tuning mechanism to stop the phase detector from adjusting the delays of individual delay cells, in which the stop-tuning mechanism comprises a combinational circuit, in which The stop-tuning mechanism takes any number of Q signals and the input data stream as inputs. The stop-tuning mechanism outputs a no-tune signal to disable the phase detector, generates the no-tune signal based on pre-programmed logic, and may or may not require a local active clock for operation.

The WuRX of the present disclosure comprises a pattern detection mechanism, in which the pattern detection mechanism may be a purely combinational circuit requiring no active clock. Alternatively, the pattern detection mechanism may require an active clock, and may take a number of Q signals as inputs. Further, the pattern detection mechanism checks the Q signals against the specific wake-up code pattern, and outputs a pattern-detected signal.

The WuRX of the present disclosure comprises a false trigger protection mechanism configured to prevent erroneous wake-ups due to false wake-up pattern signals (e.g., during start-up or noise). Further, the WuRX of the present disclosure comprises a delay chain configured such that the delay chain takes the no-tune signal as input and outputs a delayed version of the no-tune signal. Further, the WuRX of the present disclosure is configured such that a combinational circuit takes the delayed no-tune signal and the pattern-detected signal as inputs, and outputs the wake-up signal based on pre-programmed logic.

The clock generation unit of the present disclosure comprises the ability to generate a stable reference clock for digital circuit operation, and to recover carrier frequency from an OOK-modulated data stream. Further, the clock generation unit employs fast recovery of the carrier frequency from start-up (<80 μs), and has the ability to intermittently synchronize to the carrier frequency when data is present and maintain frequency when data is absent. Furthermore, the clock generation unit has the ability to maintain frequency despite prolonged absence of data (>200 ms), and to recover carrier frequency upon the first instance of an incoming data stream. Furthermore, the clock generation unit has ability to maintain operation in the absence of a local active clock, and extremely low power operation (≤352 nW).

The clock generation unit of the present disclosure comprises a ring oscillator configured as current-starved, and capable of being digitally synthesized. The ring oscillator is configured to be disabled to reduce leakage power, and operate as a free-running ring oscillator or in an open-loop architecture. The ring oscillator is configured such that the delay between inverter stages is controlled via a tuning voltage (VTune).

The clock generation unit of the present disclosure comprises a reconfigurable switch configured to reconfigure the ring oscillator into free-running mode (closed-loop) or an open-loop architecture, and to control whether the output of the ring oscillator feeds back to its input.

The clock generation unit of the present disclosure comprises a phase detector: configured to take two inputs: data-in and the output of the ring oscillator. Further, the phase detector is configured to output a tuning voltage (VTune) to adjust the delay between inverter stages. Furthermore, the phase detector is configured to be disabled via a tune-enable signal.

The clock generation unit of the present disclosure comprises a data presence detector configured to control the tune-enable signal of the phase detector, and control the reconfigurable switches. Further, the data presence detector is configured to detect the presence or absence of data within the exact clock cycle of the data becoming present or absent. Furthermore, the data presence detector is configured to achieve detection speed through delayed flip-flops (DFFs) that detect positive and negative phase differences between the clock output and data-in.

The clock generation unit of the present disclosure comprises a fast start mechanism configured to start the clock within 80 μs. Further, the fast start mechanism is configured to use a phased approach, starting in phase-locked loop (PLL) mode for fast coarse frequency acquisition and transitioning to delay-locked loop (DLL) mode for fine frequency acquisition.

One of the ordinary skills in the art will appreciate that techniques consistent with the present disclosure are applicable in other contexts as well without departing from the scope of the disclosure.

What has been described and illustrated herein are examples of the present disclosure. The terms, descriptions, and figures used herein are set forth by way of illustration and are not meant as limitations. Many variations are possible within the spirit and scope of the subject matter, which is intended to be defined by the following claims and their equivalents in which all terms are meant in their broadest reasonable sense unless otherwise indicated.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments herein may comprise hardware and software elements. The embodiments that are implemented in software include but are not limited to, firmware, resident software, microcode, a. The functions performed by various modules described herein may be implemented in other modules or combinations of other modules. For the purposes of this description, a computer-usable or computer-readable medium may be any apparatus that may comprise, store, communicate, propagate, or transport the program for use by or in connection with the instruction execution system, apparatus, or device.

A description of an embodiment with several components in communication with each other does not imply that all such components are required. On the contrary, a variety of optional components are described to illustrate the wide variety of possible embodiments of the invention. When a single device or article is described herein, it will be apparent that more than one device/article (whether or not they cooperate) may be used in place of a single device/article. Similarly, where more than one device or article is described herein (whether or not they cooperate), it will be apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries may be defined so long as the specified functions and relationships thereof are appropriately performed. Alternatives (including equivalents, extensions, variations, deviations, and the like., of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open-ended in that an item or items following any one of these words is not meant to be an exhaustive listing of such item or items or meant to be limited to the listed item or items. It must also be noted that as used herein and in the appended claims, the singular forms “a”, “an”, and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limited, of the scope of the invention, which is outlined in the following claims.

1. A communication system for energy efficient clockless wake-up receiver with dynamic clock generation in Body Area Networks (BAN) using a Human Body Communication (HBC) network comprising:
a wake-up receiver unit configured to operate in a constant active low-power mode for constantly listening to one or more input signals received from a transmitter, wherein the wake-up receiver unit operates in the constant low-power activated mode using leakage power;
an intermittently operation unit connected to the wake-up receiver unit, wherein the intermittently operation unit comprises:
a clock generation unit configured to:
switch to a clock recovery mode for extracting a clock from the one or more modulated data streams, and wherein the clock generation unit switches to a clock maintained mode, for maintaining a clock frequency during absence of the one or more modulated data streams, wherein in the clock recovery mode, the clock generation unit is configured to extract and recover a desired carrier clock frequency from the one or more modulated data streams, and in the clock maintained mode, the clock generation unit is configured to preserve a recovered clock frequency to provide a stable reference for system blocks in the absence of the one or more modulated data streams.

2. The communication system of claim 1, wherein the wake-up receiver unit comprises:
one or more primary delay cells configured to:
receive the one or more input signals from one or more data sources through a communication medium, wherein the one or more input signals comprises at least one or more modulated data streams corresponding to one or more modulation techniques;
form a delay chain by serially connecting the one or more primary delay cells, wherein the delay chain is configured to convert a serial data of the one or more input signals into one or more parallel intermediate bitstreams, and wherein each of the one or more primary delay cells are configured to generate the one or more parallel intermediate bitstreams comprising at least a half-carrier-period delayed version of a preceding delay cell associated with each of the one or more primary delay cells;
generate one or more intermediate signals, based on the generated one or more parallel intermediate bitstreams;
adjust delay of the one or more parallel intermediate bitstreams to match a clock period associated with the one or more intermediate signals with a clock period of the one or more input signals by automatically tuning a delay value of the one or more primary delay cells, wherein each of the one or more primary delay cells are tuned to a plurality of fractions of a clock period of one or more carrier signals associated with the one or more modulated data streams; and
validate tuning operation of the one or more primary delay cells, by identifying a mismatch between a phase value and a frequency value of the one or more intermediate signals, and the one or more input signals; and
a clockless comparator module configured to:
compare the one or more parallel intermediate bitstreams of the generated one or more intermediate signals, with a predefined code pattern; and
generate a wake-up signal for triggering an active state upon determining that the one or more parallel intermediate bitstreams match with the predefined code pattern.

3. The communication system of claim 1, wherein the clock generation unit is configured to:
detect the presence of a carrier clock frequency in the one or more modulated data streams;
determine the logic state of the one or more modulated data streams based on the detected presence of the carrier clock frequency; and
recover the carrier clock frequency from the one or more modulated data streams, based on the determined logic state.

4. The communication system of claim 2, wherein to adjust the delay of the one or more parallel intermediate bitstreams to match a clock period associated with the one or more intermediate signals with a clock period of the one or more input signals by automatically tuning a delay value of the one or more primary delay cells, the one or more primary delay cells are configured to:
determine a phase difference between one or more input bits associated with the one or more input signals, and the one or more parallel intermediate bitstreams, using a phase detector module;
compare the phase difference with a pre-defined value; and
adjust a delay period of the one or more parallel intermediate bitstreams associated with the one or more intermediate signals to match with the one or more modulated data streams based on the compared phase difference by automatically tuning a phase and a frequency of the one or more parallel intermediate bitstreams to match with the phase and frequency value of the one or more modulated data streams.

5. The communication system of claim 4, wherein to adjust the delay period of the one or more parallel intermediate bitstreams associated with the one or more intermediate signals to match with the one or more modulated data streams based on the compared phase difference, the one or more primary delay cells comprises:
a combinational circuit configured to output a half-carrier-clock period delayed version of the one or more input signals by generating a reset signal, based on activation of a set signal with a defined time period, wherein the reset signal corresponds to resetting operation of the one or more primary delay cells; and
an auto-calibrated delay unit coupled to the combinational circuit, wherein the auto-calibrated delay unit is configured to:
modify tuning voltages of one or more current sources associated with the auto-calibrated delay unit, with respect to an optimal value;
modulate a discharge rate of one or more capacitors associated with the auto-calibrated delay unit, based on the modified tuning voltages;
adjust a delay timing of the reset signal, based on the modulated discharge rate; and
adjust the delay period of the one or more parallel intermediate bitstreams associated with the one or more intermediate signals, based on the adjusted delay timing of the reset signal.

6. The communication system of claim 1, further comprising:
a control unit configured to:
determine whether a tuning is required to be performed on the one or more primary delay cells based on the one or more intermediate signals;
generate an interrupt signal for interrupting tuning operation of the one or more primary delay cells based on the determination if the tuning is determined to be non-essential and disruptive to normal operation, wherein the interrupt signal is generated from the adjusted-delay for the one or more parallel intermediate bitstreams;
determine an absence of the pre-defined code pattern in the generated one or more parallel intermediate bitstreams;
determine whether a false wake-up signal is generated during the absence of the pre-defined code pattern in the generated one or more parallel intermediate bitstreams;
identify an occurrence of a false triggering event based on the determination;
compare a clock time period of the one or more parallel intermediate bitstreams with a clock time period of the interrupt signal;
generate a delayed version of the interrupt signal based on the comparison; and
regenerate the wake-up signal based on the delayed version of the interrupt signal and the original wake up signal.

7. The communication system of claim 6, wherein the control unit is further configured to:
interrupt the tuning operation of the one or more primary delay cells, based on the generated interrupt signal.

8. The communication system of claim 6, wherein to regenerate the wake-up signal based on the delayed version of the interrupt signal, the control unit is configured to:
match an offset value of the interrupt signal with an offset value corresponding to the one or more parallel intermediate bitstreams, using one or more secondary delay cells, based on the adjusted delay value;
perform AND logic operation on the interrupt signal and the one or more parallel intermediate bitstreams, based on matched offset values; and
regenerate the wake-up signal, based on the performed AND logic operation.

9. The communication system of claim 1, wherein the clock generation unit is configured to:
operate in a Delay-Locked Loop (DLL) mode, when the one or more modulated data streams associated with the one or more input signals corresponds to a primary baseband logic value, wherein the DLL mode corresponds to recovering the carrier clock frequency from the one or more input signals, and wherein the primary baseband logic value corresponds to presence of the carrier clock frequency in the one or more input signals; and
operate in a free-running mode, when the one or more modulated data streams associated with the one or more input signals corresponds to a secondary baseband logic value, wherein the free-running mode corresponds to setting the recovered carrier clock frequency as a constant value, and wherein the secondary baseband logic value corresponds to absence of the carrier clock frequency in the one or more input signals.

10. The communication system of claim 9, wherein the clock generation unit comprises:
one or more flip flop units configured to switch the clock generation unit between the DLL mode, and the free-running mode by:
detecting a positive phase difference value between the one or more input signals, and an output of a clock module associated with the clock generation unit, using primary flip flop units;
detecting a negative phase difference value between the one or more input signals, and the output of the clock module associated with the clock generation unit, using secondary flip flop units;
determining presence of data in the one or more input signals by performing a set of logic operations on output of one of the secondary flip flop unit and the primary flip flop unit; and
switching the clock generation unit between the DLL mode, and the free-running mode, based on the determined one of a presence and absence of the data in the one or more input signals.

11. The communication system of claim 3, wherein to recover the carrier clock frequency from the one or more modulated data streams, based on the determined logic state, the clock generation unit is configured to:
synchronize a clock frequency of the clock generation unit to the carrier clock frequency of the one or more modulated data streams, when the one or more modulated data streams associated with the one or more input signals corresponds to a primary baseband logic value; and
recover the carrier clock frequency from the one or more modulated data streams, based on the synchronization.

12. The communication system of claim 11, wherein to synchronize the clock frequency of the clock generation unit to the carrier clock frequency of the one or more modulated data streams, when the one or more modulated data streams associated with the one or more input signals corresponds to the primary baseband logic value, clock generation unit comprises:
an oscillator module configured to:
determine if one or more primary switches associated with the oscillator module are closed, and if one or more secondary switches associated with the oscillator module are open;
modify tuning voltages of one or more current sources associated with the clock generation unit, with respect to an optimal value, wherein the tuning voltages are modified using a phase detector module;
adjust a delay value of one or more inverters associated with the clock generation unit based on the modified tuning voltages, wherein the phase detector module is configured to compare each input signal with an output of the oscillator module to adjust the delay of the one or more inverters; and
synchronize the clock frequency of the clock generation unit to the carrier clock frequency of the one or more modulated data streams, based on the adjusted delay value.

13. The communication system of claim 12, wherein the oscillator module is further configured:
determine if the one or more primary switches associated with the oscillator module of the clock generation unit are open, and if the one or more secondary switches associated with the oscillator module of the clock generation unit are closed;
operate in a free-running mode, based on the determination, wherein the free-running mode corresponds to a closed loop configuration of the oscillator module, wherein the closed loop configuration corresponds to a direct connection between an input and an output of the oscillator module;
generate a constant delay value for the one or more inverters associated with the clock generation unit, by terminating the tuning operation in the oscillator module; and
set the recovered carrier clock frequency as a constant value, based on the generated constant delay value for the one or more inverters.

14. The communication system of claim 1, wherein the wake-up receiver unit is configured to:
continuously monitor incoming one or more input signals from the transmitter by remaining in a constant power on and listening mode;
operate in the listening mode, during an absence of data and until the one or more input signals are received from the transmitter; and
remain in leakage power mode while actively processing the one or more input signals received from the transmitter.

15. A communication method for energy efficient clockless wake-up receiver with dynamic clock generation in Body Area Networks (BAN) using a Human Body Communication (HBC) network comprising:
operating, by a wake-up receiver unit, in a constant active low-power mode for constantly listening to one or more input signals received from a transmitter, wherein the wake-up receiver unit operates in the constant low-power activated mode using leakage power; and
switching, by a clock generation unit, to a clock recovery mode for extracting a clock from the one or more modulated data streams, and wherein the clock generation unit switches to a clock maintained mode, for maintaining a clock frequency during absence of the one or more modulated data streams, wherein in the clock recovery mode, the clock generation unit is configured to extract and recover a desired carrier clock frequency from the one or more modulated data streams, and in the clock maintained mode, the clock generation unit is configured to preserve a recovered clock frequency to provide a stable reference for system blocks in the absence of the one or more modulated data streams.

16. The communication method of claim 15, further comprising:
receiving, by one or more primary delay cells, the one or more input signals from one or more data sources through a communication medium, wherein the one or more input signals comprises at least one or more modulated data streams corresponding to one or more modulation techniques;
forming, by the one or more primary delay cells, a delay chain by serially connecting the one or more primary delay cells, wherein the delay chain is configured to convert a serial data of the one or more input signals into one or more parallel intermediate bitstreams, and wherein each of the one or more primary delay cells are configured to generate the one or more parallel intermediate bitstreams comprising at least a half-carrier-period delayed version of a preceding delay cell associated with each of the one or more primary delay cells;
generating, by the one or more primary delay cells, one or more intermediate signals, based on the generated one or more parallel intermediate bitstreams;
adjusting, by the one or more primary delay cells, delay of the one or more parallel intermediate bitstreams to match a clock period associated with the one or more intermediate signals with a clock period of the one or more input signals by automatically tuning a delay value of the one or more primary delay cells, wherein each of the one or more primary delay cells are tuned to a plurality of fractions of a clock period of one or more carrier signals associated with the one or more modulated data streams;
validating, by the one or more primary delay cells, tuning operation of the one or more primary delay cells, by identifying a mismatch between a phase value and a frequency value of the one or more intermediate signals, and the one or more input signals;
comparing, by a clockless comparator module, the one or more parallel intermediate bitstreams of the generated one or more intermediate signals, with a predefined code pattern; and
generating, by the clockless comparator module, a wake-up signal for triggering an active state upon determining that the one or more parallel intermediate bitstreams match with the predefined code pattern.

17. The communication method of claim 15, further comprising:
detecting, by the clock generation unit, the presence of a carrier clock frequency in the one or more modulated data streams;
determining, by the clock generation unit, the logic state of the one or more modulated data streams based on the detected presence of the carrier clock frequency; and
recovering, by the clock generation unit, the carrier clock frequency from the one or more modulated data streams, based on the determined logic state.

18. The communication method of claim 16, wherein adjusting the delay of the one or more parallel intermediate bitstreams to match a clock period associated with the one or more intermediate signals with a clock period of the one or more input signals by automatically tuning a delay value of the one or more primary delay cells, comprises:
determining, by the one or more primary delay cells, a phase difference between one or more input bits associated with the one or more input signals, and the one or more parallel intermediate bitstreams, using a phase detector module;
comparing, by the one or more primary delay cells, the phase difference with a pre-defined value; and
adjusting, by the one or more primary delay cells, a delay period of the one or more parallel intermediate bitstreams associated with the one or more intermediate signals to match with the one or more modulated data streams based on the compared phase difference by automatically tuning a phase and a frequency of the one or more parallel intermediate bitstreams to match with the phase and frequency value of the one or more modulated data streams.

19. The communication method of claim 18, wherein adjusting the delay period of the one or more parallel intermediate bitstreams associated with the one or more intermediate signals to match with the one or more modulated data streams based on the compared phase difference, comprises:
outputting, by a combinational circuit, a half-carrier-clock period delayed version of the one or more input signals by generating a reset signal, based on activation of a set signal with a defined time period, wherein the reset signal corresponds to resetting operation of the one or more primary delay cells;
modifying, by an auto-calibrated delay unit, tuning voltages of one or more current sources associated with the auto-calibrated delay unit, with respect to an optimal value;
modulating, by the auto-calibrated delay unit, a discharge rate of one or more capacitors associated with the auto-calibrated delay unit, based on the modified tuning voltages;
adjusting, by the auto-calibrated delay unit, a delay timing of the reset signal, based on the modulated discharge rate; and
adjusting, by the auto-calibrated delay unit, the delay period of the one or more parallel intermediate bitstreams associated with the one or more intermediate signals, based on the adjusted delay timing of the reset signal.

20. The communication method of claim 15, further comprising:
determining, by a control unit, whether a tuning is required to be performed on the one or more primary delay cells based on the one or more intermediate signals;
generating, by the control unit, an interrupt signal for interrupting tuning operation of the one or more primary delay cells based on the determination if the tuning is determined to be non-essential and disruptive to normal operation, wherein the interrupt signal is generated from the adjusted-delay for the one or more parallel intermediate bitstreams;
determining, by the control unit, an absence of the pre-defined code pattern in the generated one or more parallel intermediate bitstreams;
determining, by the control unit, whether a false wake-up signal is generated during the absence of the pre-defined code pattern in the generated one or more parallel intermediate bitstreams;
identifying, by the control unit, an occurrence of a false triggering event based on the determination;
comparing, by the control unit, a clock time period of the one or more parallel intermediate bitstreams with a clock time period of the interrupt signal;
generating, by the control unit, a delayed version of the interrupt signal based on the comparison; and
regenerating, by the control unit, the wake-up signal based on the delayed version of the interrupt signal and the original wake up signal.
